(19) United States
(12) Patent Application Publication
(10) Pub. No.: US 2024/0230558 A9
(43) Pub. Date: Jul. 11, 2024

(54) INSPECTION SYSTEM

(71) Applicant: TATSUMI RYOKI CO., LTD, Tokyo (JP)

(72) Inventor: Toyoshi KONDO, Tokyo (JP)

(21) Appl. No.: 18/278,573

(22) PCT Filed: Feb. 28, 2022
(86) PCT No.: PCT/JP2022/008172

§ 371 Date: Aug. 23, 2023

(30) Foreign Application Priority Data
Mar. 17, 2021 (JP) 2021-043220

(51) Int. Cl. G01N 22/02; G01R 31/327

(52) U.S. Cl. CPC G01N 22/02; G01R 31/3278

(57) ABSTRACT

A inspection system includes: a transmission unit that transmits a signal to inspect an inspection target object; a receipt unit that receives the signal from the transmission unit; and a totaling unit. The transmission unit and the receipt unit have a positional relationship that the transmission unit and the receipt unit sandwich the inspection target object. On the basis of at least one of radio-wave strength or signal waveform of the signal from the transmission unit and received by the receipt unit, the totaling unit determines whether or not there is a failure in the inspection target object. The inspection target object is resistors of a load-testing apparatus. A holding frame that holds the resistors is made of an insulator. The holding frame, the transmission unit, and the receipt unit are surrounded by a radio-wave-shielding member. The load-testing apparatus is provided with a grounding relay.

### TECHNICAL FIELD

The present invention relates to an inspection system.

### BACKGROUND ART

As in Patent Literature 1, a load-testing apparatus that measures a current value or measures a temperature to detect a failure has been proposed.

### CITATION LIST

### Patent Literature

Patent Literature 1: Japanese Patent No. 5551324

### SUMMARY OF INVENTION

### Technical Problem

However, wiring in the load-testing apparatus may be complicated.

Therefore, an object of the present invention is to provide an inspection system that can easily detect a failure of an inspection target object.

### Solution to Problem

An inspection system according to the present invention includes: a transmission unit that transmits a signal to inspect an inspection target object; a receipt unit that receives the signal from the transmission unit; and a totaling unit.

The transmission unit and the receipt unit have a positional relationship that the transmission unit and the receipt unit sandwich the inspection target object.

On the basis of at least one of radio-wave strength or signal waveform of the signal from the transmission unit and received by the receipt unit, the totaling unit determines whether or not there is a failure in the inspection target object.

The transmission unit and the receipt unit are disposed and have a positional relationship that the transmission unit and the receipt unit sandwich the inspection target object. On the basis of the radio-wave strength or the like of the signal transmitted from the transmission unit and received by the receipt unit, it is possible to easily detect a failure of said inspection target region.

Preferably, the inspection target object may be resistors of a load-testing apparatus.

A holding frame that holds the resistors may be made of an insulator.

The holding frame, the transmission unit, and the receipt unit may be surrounded by a radio-wave-shielding member.

The load-testing apparatus may be provided with a grounding relay to which the resistors are grounded when the inspection is performed.

Without a change in the internal structure of the load-testing apparatus (in particular, the holding frame), and without an effect on the electric wiring of the resistors, it is possible to detect a failure inside said holding frame.

In addition, detection of a failure can be performed at a stage before a load test is actually performed.

Since the holding frame is made of an insulator, radio waves can easily pass through the inside of the holding frame.

Further preferably, in the load-testing apparatus, a lid may be provided for at least one of an air outlet and an air inlet, the lid includes a radio-wave-shielding member, and the lid is turned into an open state when a load test using the resistors is performed, and is turned into a closed state when the inspection is performed.

Further preferably, the load-testing apparatus may be for performing a load test of a three-phase alternating-current generator.

The load-testing apparatus may be provided with a relay for short-circuiting R-phase, S-phase, and T-phase resistors of the resistors, and the grounding relay, which is provided between the relay and a grounded surface and is for performing on/off-switching of grounding of the resistors.

The grounding relay is connected to the short-circuit side of the short-circuit relay, so that the resistors can be grounded easily as compared with an embodiment in which grounding is performed at another place.

Alternatively, preferably, at least the inspection target object, the transmission unit, and the receipt unit may be surrounded by a radio-wave-shielding member.

A communication means of communication between the transmission unit and the receipt unit may transmit its own identification information to the outside while wireless communication means is in an on state, and the communication means may be performed with wireless communication of a frequency that does not pass through the radio-wave-shielding member.

Since a region that surrounds the inspection target region, the transmission unit, and the receipt unit is covered with the radio-wave-shielding member, it is possible to reduce the possibility that radio waves transmitted from the transmission unit reach the receipt unit through a region except the inspection target region.

Further preferably, communication between the receipt unit and the totaling unit may be performed with wired communication or wireless communication of a frequency that passes through the radio-wave-shielding member.

### Advantageous Effects of Invention

As described above, according to the present invention, an inspection system can be provided.

### BRIEF DESCRIPTION OF DRAWINGS

FIG. 1 is a perspective view of a load-testing apparatus according to a first embodiment.

FIG. 2 is a schematic diagram illustrating the configuration of the load-testing apparatus according to the first embodiment.

FIG. 3 is a cross-sectional configuration diagram of a region including a 11th holding frame and a 12th holding frame when viewed from the front.

FIG. 4 is a perspective view of a first main relay unit to a third main relay unit, a first resistance unit, a second resistance unit, a 10th resistance unit, a 20th resistance unit, and a cooling unit according to the first embodiment.

FIG. 5 is an enlarged perspective view of a region including the first main relay unit to the third main relay unit, the first resistance unit, and the second resistance unit in FIG. 4.

FIG. 6 is an enlarged perspective view of a region including the 10th resistance unit, the 20th resistance unit, and the cooling unit in FIG. 4.

FIG. 7 is a circuit diagram of the first resistance unit, the second resistance unit, the 10th resistance unit, and the 20th resistance unit.

FIG. 8 is a circuit diagram of the first resistance unit, the second resistance unit, the 10th resistance unit, and the 20th resistance unit in a state where resistor groups adjacent in a y direction are connected in series and power supply to the first resistance unit is performed.

FIG. 9 is a circuit diagram of the first resistance unit, the second resistance unit, the 10th resistance unit, and the 20th resistance unit in a state where the resistor groups adjacent in the y direction are connected in parallel and power supply to the first resistance unit is performed.

FIG. 10 is a circuit diagram of the first resistance unit, the second resistance unit, the 10th resistance unit, and the 20th resistance unit in a state where the resistor groups adjacent in the y direction are connected in series and power supply to the first resistance unit and the second resistance unit is performed.

FIG. 11 is a circuit diagram of the first resistance unit, the second resistance unit, the 10th resistance unit, and the 20th resistance unit in a state where the resistor groups adjacent in the y direction are connected in parallel and power supply to the first resistance unit and the second resistance unit is performed.

FIG. 12 is a circuit diagram of the first resistance unit, the second resistance unit, the 10th resistance unit, and the 20th resistance unit in a state where the resistor groups adjacent in the y direction are connected in series and power supply to the first resistance unit, the second resistance unit, and the 10th resistance unit is performed.

FIG. 13 is a circuit diagram of the first resistance unit, the second resistance unit, the 10th resistance unit, and the 20th resistance unit in a state where the resistor groups adjacent in the y direction are connected in parallel and power supply to the first resistance unit, the second resistance unit, and the 10th resistance unit is performed.

FIG. 14 is a circuit diagram of the first resistance unit, the second resistance unit, the 10th resistance unit, and the 20th resistance unit in a state where power supply to only half of the resistor groups of the first resistance unit, the second resistance unit, and the 10th resistance unit is performed.

FIG. 15 is a circuit diagram of the first resistance unit, the second resistance unit, the 10th resistance unit, and the 20th resistance unit in a state where no failure occurs at a time of inspection.

FIG. 16 is a circuit diagram of the first resistance unit, the second resistance unit, the 10th resistance unit, and the 20th resistance unit in a state where a failure occurs at a time of inspection.

FIG. 17 is a cross-sectional configuration diagram of a region including a 11th holding frame and a 12th holding frame when viewed from the front, in an embodiment in which no wall is provided between the 11th holding frame and the 12th holding frame.

FIG. 18 is a schematic diagram illustrating the configuration of a load-testing apparatus according to a second embodiment.

FIG. 19 is a perspective view of a first main relay unit to a third main relay unit, a first resistance unit to a seventh resistance unit, a 10th resistance unit to a 50th resistance unit, and a cooling unit according to the second embodiment.

FIG. 20 is a circuit diagram of the first resistance unit to the fourth resistance unit according to the second embodiment.

FIG. 21 is a circuit diagram of the fifth resistance unit to the seventh resistance unit, and the 10th resistance unit according to the second embodiment.

FIG. 22 is a circuit diagram of the 20th resistance unit to the 50th resistance unit according to the second embodiment.

### DESCRIPTION OF EMBODIMENTS

Hereinafter, a first embodiment will be described with reference to the drawings.

Note that embodiments are not limited to the following embodiments. In addition, the contents described in one of the embodiments are similarly applied to the other embodiments in principle. In addition, each embodiment and each modification can be appropriately combined.

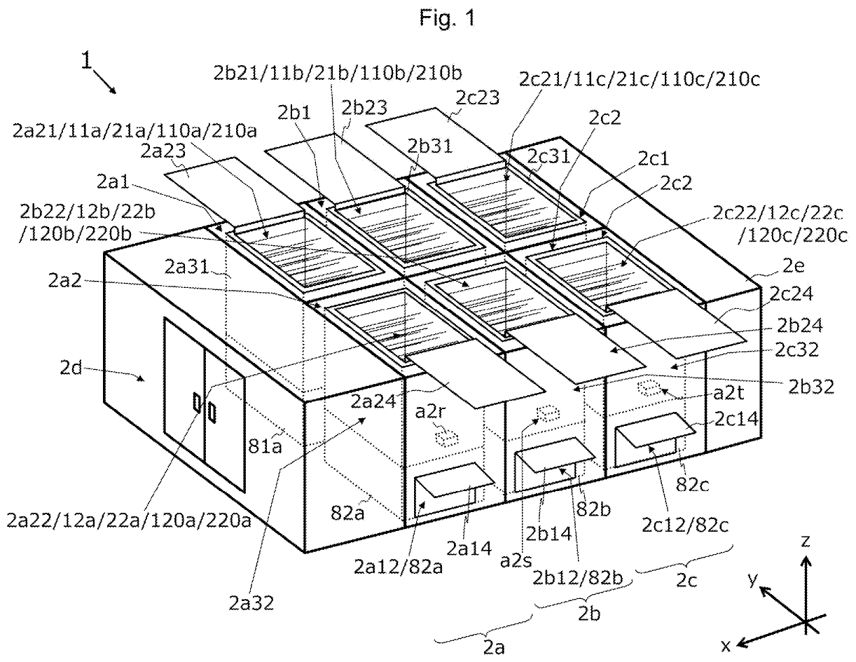

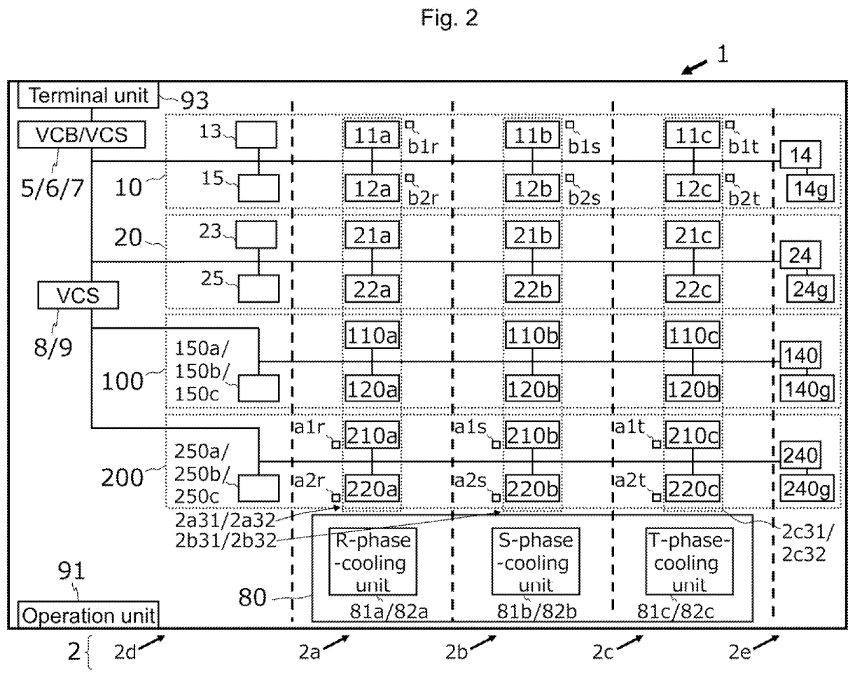

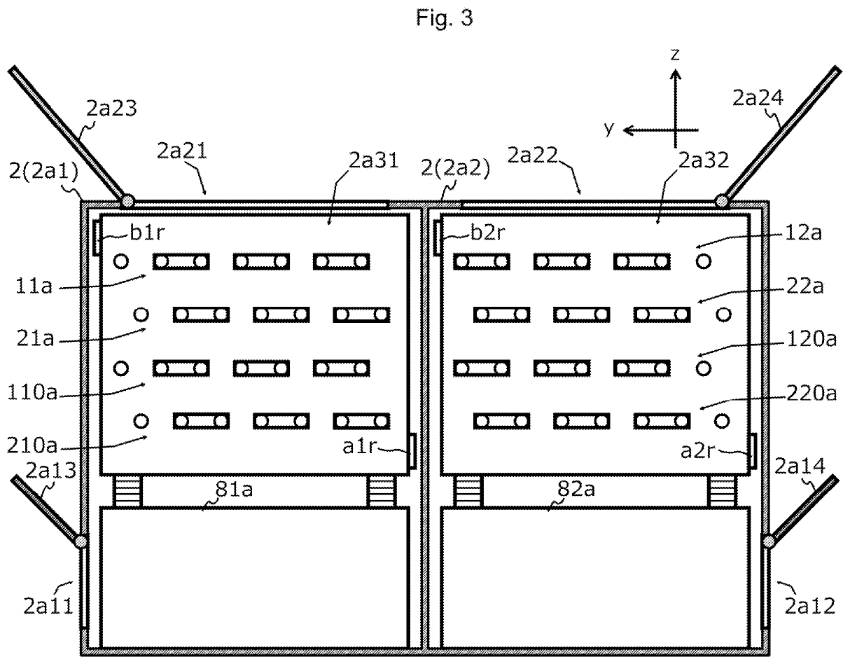

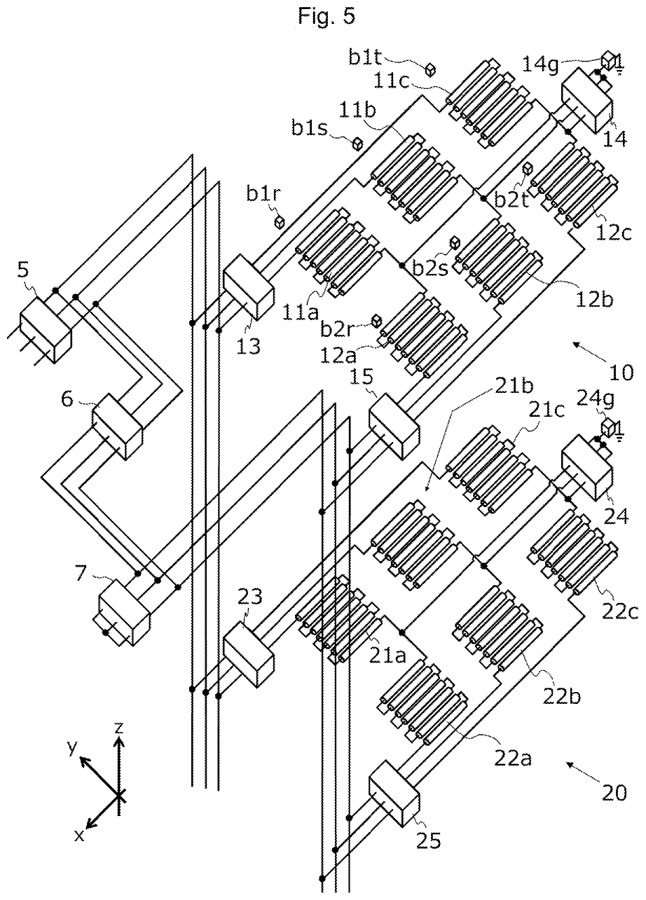

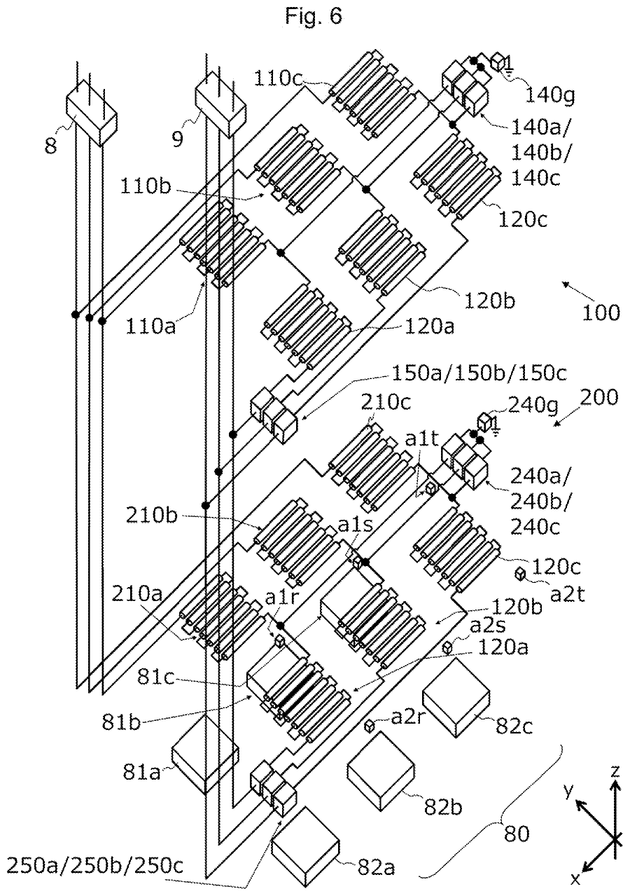

A dry-type load-testing apparatus 1 according to the first embodiment includes a housing 2, main relay units (a first main relay unit 5, a second main relay unit 6, and a third main relay unit 7), a first fine-adjustment relay unit 8, a second fine-adjustment relay unit 9, a first resistance unit 10, a second resistance unit 20, a 10th resistance unit 100, a 20th resistance unit 200, a cooling unit 80, an operation unit 91, and a terminal unit 93 (see FIGS. 1 to 16).

In the load-testing apparatus 1, transmission units, receipt units, a totaling unit, radio-wave-shielding members, and grounding relays constitute an inspection system that detects a failure of an inspection target object, such as a resistor.

The transmission units described herein include an R-phase transmission unit ar, a first R-phase transmission unit a1r, a second R-phase transmission unit a2r, a first S-phase transmission unit a1s, a second S-phase transmission unit a2s, a first T-phase transmission unit a1t, and a second T-phase transmission unit a2t, which will be described later.

In addition, the receipt units include an R-phase receipt unit br, a first R-phase receipt unit b1r, a second R-phase receipt unit b2r, a first S-phase receipt unit b1s, a second S-phase receipt unit b2s, a first T-phase receipt unit b1t, and a second T-phase receipt unit b2t, which will be described later.

In addition, the totaling unit includes the operation unit 91, which will be described later.

The radio-wave-shielding members include a 11th accommodating region 2a1, a 12th accommodating region 2a2, a 21st accommodating region 2b1, a 22nd accommodating region 2b2, a 31st accommodating region 2c1, a 32nd accommodating region 2c2, a first R-phase air inlet lid 2a13, a second R-phase air inlet lid 2a14, a first R-phase air outlet lid 2a23, a second R-phase air outlet lid 2a24, a first S-phase air inlet lid 2b13, a second S-phase air inlet lid 2b14, a first S-phase air outlet lid 2b23, a second S-phase air outlet lid 2b24, a first T-phase air inlet lid 2c13, a second T-phase air inlet lid 2c14, a first T-phase air outlet lid 2c23, and a second T-phase air outlet lid 2c24, which will be described later.

The grounding relays include a 14th grounding relay 14g to a 74th grounding relay 74g, and a 140th grounding relay 140g to a 540th grounding relay 540g, which will be described later.

Note that directions are described with an x direction which is a horizontal direction (front-rear direction) in which a first accommodating region 2a and a second accommodating region 2b of the housing 2 are arranged, a y direction which is a horizontal direction (left-right direction) perpendicular to the x direction, and a z direction which is a vertical direction perpendicular to the x direction and the y direction. In FIGS. 1 and 3 to 6, and FIG. 19 of a second embodiment, directions indicated by arrows of xyz axes are defined as a forward direction, a right direction, and an upward direction, respectively.

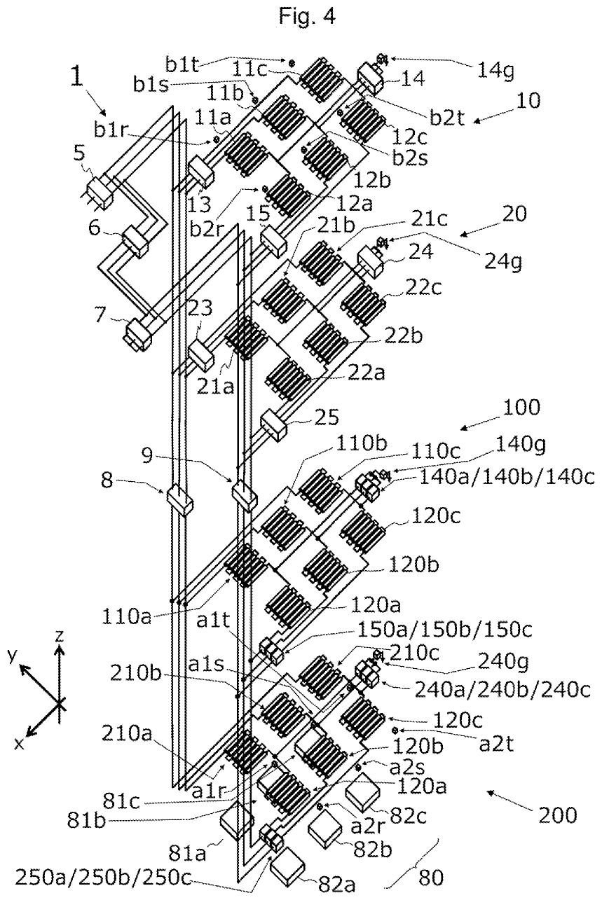

In addition, FIGS. 4 to 6 illustrate the configurations of the first resistance unit 10, the second resistance unit 20, the 10th resistance unit 100, and the 20th resistance unit 200 in a state where the spaces in the z direction are widened.

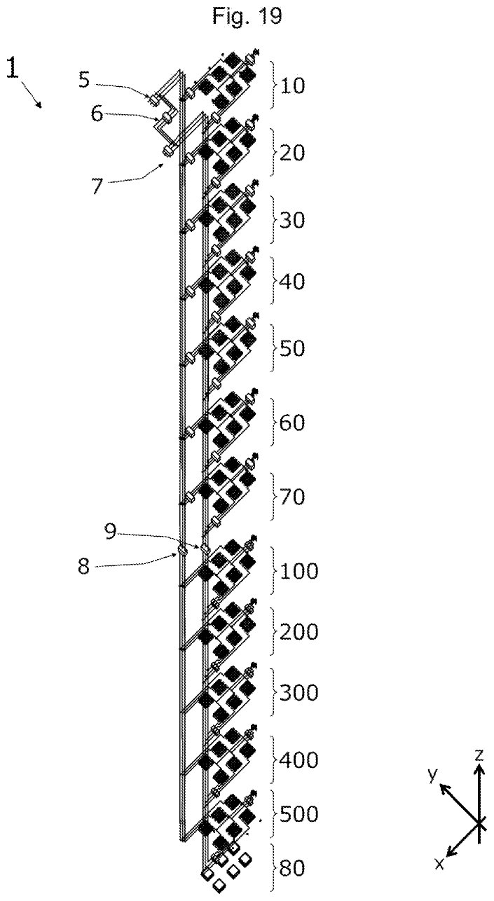

In addition, FIG. 19 of the second embodiment illustrates the configurations of a first resistance unit 10 to a seventh resistance unit 70, and a 10th resistance unit 100 to a 50th resistance unit 500 in a state where the spaces in the z direction are widened.

In addition, in FIG. 1, in order to illustrate the internal structure, such as the second R-phase transmission unit a2r, part of portions that are not visible from the outside are illustrated with dotted lines.

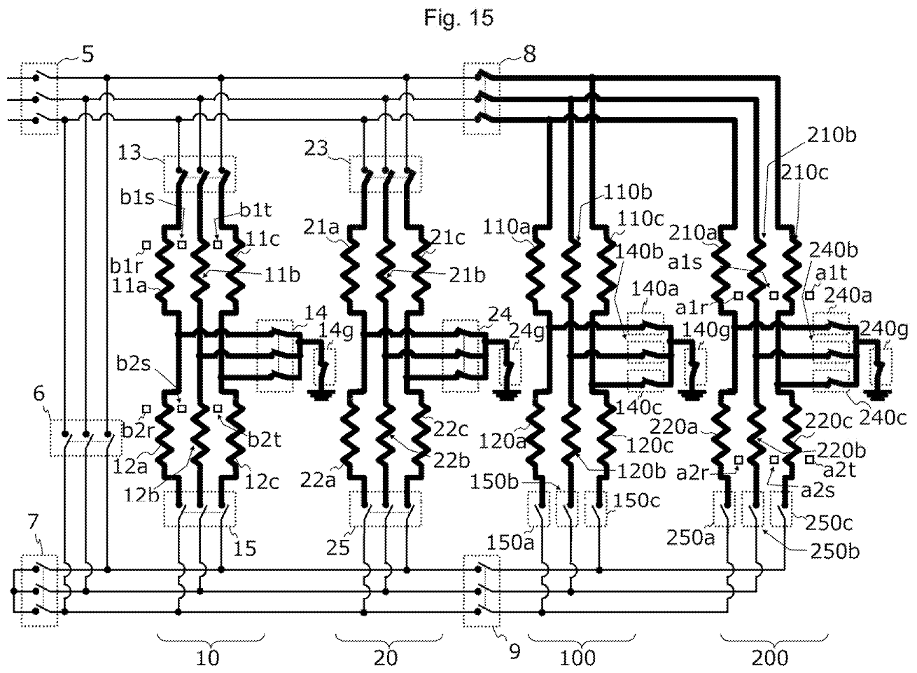

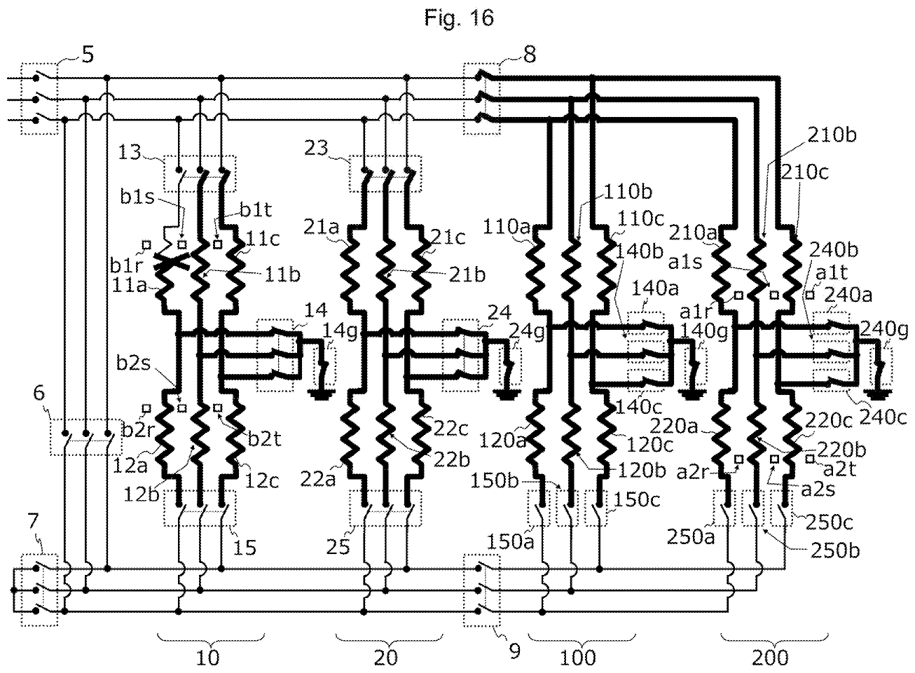

In addition, in FIGS. 15 and 16, portions having the same potential as a grounded surface are illustrated with thick lines.

(Housing 2)

The housing 2 accommodates the first main relay unit 5, the second main relay unit 6, the third main relay unit 7, the first fine-adjustment relay unit 8, the second fine-adjustment relay unit 9, the first resistance unit 10, the second resistance unit 20, the 10th resistance unit 100, the 20th resistance unit 200, the cooling unit 80, the operation unit 91, and the terminal unit 93.

The housing 2 has the first accommodating region 2a, the second accommodating region 2b, a third accommodating region 2c, a fourth accommodating region 2d, and a fifth accommodating region 2e (see FIGS. 1 to 6).

Arranged from the x-direction front side are the fourth accommodating region 2d, the first accommodating region 2a, the second accommodating region 2b, the third accommodating region 2c, and the fifth accommodating region 2e.

That is, the first accommodating region 2a, the second accommodating region 2b, and the third accommodating region 2c in the housing 2 are located between the fourth accommodating region 2d and the fifth accommodating region 2e in the housing 2.

The second accommodating region 2b is located between the first accommodating region 2a and the third accommodating region 2c.

(First Accommodating Region 2a)

The first accommodating region (R-phase-resistor-group-accommodating region) 2a has the 11th accommodating region 2a1 and the 12th accommodating region 2a2.

The 12th accommodating region 2a2 is provided to the left of the 11th accommodating region 2a1 in the y direction.

The 11th accommodating region (first R-phase-resistor-group-accommodating region) 2a1 accommodates a 11th holding frame 2a31 in the upper section, and accommodates a first R-phase-cooling unit 81a of the cooling unit 80 in the lower section.

The 12th accommodating region (second R-phase-resistor-group-accommodating region) 2a2 accommodates a 12th holding frame 2a32 in the upper section, and accommodates a second R-phase-cooling unit 82a of the cooling unit 80 in the lower section.

Provided at a lower portion of the 11th accommodating region 2a1 is a first R-phase air inlet 2a11.

Provided at a lower portion of the 12th accommodating region 2a2 is a second R-phase air inlet 2a12.

Provided at an upper portion of the 11th accommodating region 2a1 is a first R-phase air outlet 2a21.

Provided at an upper portion of the 12th accommodating region 2a2 is a second R-phase air outlet 2a22.

Air taken in through the first R-phase air inlet 2a11 by the first R-phase-cooling unit 81a of the cooling unit 80 cools a 210th R-phase resistor group 210a, a 110th R-phase resistor group 110a, a 21st R-phase resistor group 21a, and an 11th R-phase resistor group 11a, and is discharged through the first R-phase air outlet 2a21.

Air taken in through the second R-phase air inlet 2a12 by the second R-phase-cooling unit 82a of the cooling unit 80 cools a 220th R-phase resistor group 220a, a 120th R-phase resistor group 120a, a 22nd R-phase resistor group 22a, and a 12th R-phase resistor group 12a, and is discharged through the second R-phase air outlet 2a22.

The first R-phase air inlet 2a11, the second R-phase air inlet 2a12, the first R-phase air outlet 2a21, and the second R-phase air outlet 2a22 are provided with lids (the first R-phase air inlet lid 2a13, the second R-phase air inlet lid 2a14, the first R-phase air outlet lid 2a23, and the second R-phase air outlet lid 2a24), which close when the inlets and outlets are not used, that is, when a load test is not performed, and at a time of an inspection, which will be described later, of the load-testing apparatus 1. These lids (first R-phase air inlet lid 2a13, second R-phase air inlet lid 2a14, first R-phase air outlet lid 2a23, and second R-phase air outlet lid 2a24) may be electrically opened and closed on the basis of operation of the operation unit 91 or the like, or may be manually opened and closed by the user. However, these lids may be omitted.

Sides of the 11th accommodating region 2a1, sides of the 12th accommodating region 2a2, the first R-phase air inlet lid 2a13, the second R-phase air inlet lid 2a14, the first R-phase air outlet lid 2a23, and the second R-phase air outlet lid 2a24 are configured by walls of metallic members, such as aluminum plates.

The 11th holding frame 2a31 has a substantially-quadrangular-tubular shape that is open in an up-down direction.

The 11th holding frame 2a31 is made of an insulator. Sides of the 11th holding frame 2a31 hold the 11th R-phase resistor group 11a of the first resistance unit 10, the 21st R-phase resistor group 21a of the second resistance unit 20, the 110th R-phase resistor group 110a of the 10th resistance unit 100, and the 210th R-phase resistor group 210a of the 20th resistance unit 200.

The 11th holding frame 2a31 is held by the first R-phase-cooling unit 81a in the lower section, through an insulator or the like.

Provided at a lower portion of the 11th holding frame 2a31, between an outer wall of the 11th holding frame 2a31 and an inner wall of the 11th accommodating region 2a1 is the first R-phase transmission unit a1r. That is, the first R-phase transmission unit a1r is provided on a surface of an outer wall of the 11th holding frame 2a31, the surface facing the 12th holding frame 2a32 in the y direction.

Provided at an upper portion of the 11th holding frame 2a31, between an inner wall of the 11th accommodating region 2a1 and an outer wall of the 11th holding frame 2a31, the outer wall having a positional relationship that the outer wall and the first R-phase transmission unit a1r sandwich the 11th holding frame 2a31 in the y direction when viewed from above, is the first R-phase receipt unit b1r. That is, the first R-phase receipt unit b1r is provided on a surface of an outer wall of the 11th holding frame 2a31, the surface being opposite a surface of the outer wall that faces the 12th holding frame 2a32 in the y direction.

The 12th holding frame 2a32 has a substantially-quadrangular-tubular shape that is open in an up-down direction.

The 12th holding frame 2a32 is made of an insulator. Sides of the 12th holding frame 2a32 hold the 12th R-phase resistor group 12a of the first resistance unit 10, the 22nd R-phase resistor group 22a of the second resistance unit 20, the 120th R-phase resistor group 120a of the 10th resistance unit 100, and the 220th R-phase resistor group 220a of the 20th resistance unit 200.

The 12th holding frame 2a32 is held by the second R-phase-cooling unit 82a in the lower section, through an insulator or the like.

Provided at a lower portion of the 12th holding frame 2a32, between an outer wall of the 12th holding frame 2a32 and an inner wall of the 12th accommodating region 2a2 is the second R-phase transmission unit a2r. That is, the second R-phase transmission unit a2r is provided on a surface of an outer wall of the 12th holding frame 2a32, the surface being opposite a surface of the outer wall that faces the 11th holding frame 2a31 in the y direction.

Provided at an upper portion of the 12th holding frame 2a32, between an inner wall of the 12th accommodating region 2a2 and an outer wall of the 12th holding frame 2a32, the outer wall having a positional relationship that the outer wall and the second R-phase transmission unit a2r sandwich the 12th holding frame 2a32 in the y direction when viewed from above, is the second R-phase receipt unit b2r. That is, the second R-phase receipt unit b2r is provided on a surface of an outer wall of the 12th holding frame 2a32, the surface facing the 11th holding frame 2a31 in the y direction.

The second accommodating region (S-phase-resistor-group-accommodating region) 2b has the 21st accommodating region 2b1 and the 22nd accommodating region 2b2.

The 22nd accommodating region 2b2 is provided to the left of the 21st accommodating region 2b1 in the y direction.

The 21st accommodating region (first S-phase-resistor-group-accommodating region) 2b1 accommodates a 21st holding frame 2b31 in the upper section, and accommodates a first S-phase-cooling unit 81b of the cooling unit 80 in the lower section.

The 22nd accommodating region (second S-phase-resistor-group-accommodating region) 2b2 accommodates a 22nd holding frame 2b32 in the upper section, and accommodates a second S-phase-cooling unit 82b of the cooling unit 80 in the lower section.

Provided at a lower portion of the 21st accommodating region 2b1 is a first S-phase air inlet 2b11 (not illustrated).

Provided at a lower portion of the 22nd accommodating region 2b2 is a second S-phase air inlet 2b12.

Provided at an upper portion of the 21st accommodating region 2b1 is a first S-phase air outlet 2b21.

Provided at an upper portion of the 22nd accommodating region 2b2 is a second S-phase air outlet 2b22.

Air taken in through the first S-phase air inlet 2b11 by the first S-phase-cooling unit 81b of the cooling unit 80 cools a 210th S-phase resistor group 210b, a 110th S-phase resistor group 110b, a 21st S-phase resistor group 21b, and an 11th S-phase resistor group 11b, and is discharged through the first S-phase air outlet 2b21.

Air taken in through the second S-phase air inlet 2b12 by the second S-phase-cooling unit 82b of the cooling unit 80 cools a 220th S-phase resistor group 220b, a 120th S-phase resistor group 120b, a 22nd S-phase resistor group 22b, and a 12th S-phase resistor group 12b, and is discharged through the second S-phase air outlet 2b22.

The first S-phase air inlet 2b11, the second S-phase air inlet 2b12, the first S-phase air outlet 2b21, and the second S-phase air outlet 2b22 are provided with lids (the first S-phase air inlet lid 2b13, the second S-phase air inlet lid 2b14, the first S-phase air outlet lid 2b23, and the second S-phase air outlet lid 2b24), which close when the inlets and outlets are not used, that is, when a load test is not performed, and at a time of an inspection, which will be described later, of the load-testing apparatus 1. These lids (first S-phase air inlet lid 2b13, second S-phase air inlet lid 2b14, first S-phase air outlet lid 2b23, and second S-phase air outlet lid 2b24) may be electrically opened and closed on the basis of operation of the operation unit 91 or the like, or may be manually opened and closed by the user. However, these lids may be omitted.

Note that the first S-phase air inlet lid 2b13 faces the second S-phase air inlet lid 2b14 in the y direction, and is provided at a position invisible in FIG. 1.

Sides of the 21st accommodating region 2b1, sides of the 22nd accommodating region 2b2, the first S-phase air inlet lid 2b13, the second S-phase air inlet lid 2b14, the first S-phase air outlet lid 2b23, and the second S-phase air outlet lid 2b24 are configured by walls of metallic members, such as aluminum plates.

The 21st holding frame 2b31 has a substantially-quadrangular-tubular shape that is open in an up-down direction.

The 21st holding frame 2b31 is made of an insulator. Sides of the 21st holding frame 2b31 hold the 11th S-phase resistor group 11b of the first resistance unit 10, the 21st S-phase resistor group 21b of the second resistance unit 20, the 110th S-phase resistor group 110b of the 10th resistance unit 100, and the 210th S-phase resistor group 210b of the 20th resistance unit 200.

The 21st holding frame 2b31 is held by the first S-phase-cooling unit 81b in the lower section, through an insulator or the like.

Provided at a lower portion of the 21st holding frame 2b31, between an outer wall of the 21st holding frame 2b31 and an inner wall of the 21st accommodating region 2b1 is the first S-phase transmission unit a1s. That is, the first S-phase transmission unit a1s is provided on a surface of an outer wall of the 21st holding frame 2b31, the surface facing the 22nd holding frame 2b32 in the y direction.

Provided at an upper portion of the 21st holding frame 2b31, between an inner wall of the 21st accommodating region 2b1 and an outer wall of the 21st holding frame 2b31, the outer wall having a positional relationship that the outer wall and the first S-phase transmission unit a1s sandwich the 21st holding frame 2b31 in the y direction when viewed from above, is the first S-phase receipt unit b1s. That is, the first S-phase receipt unit b1s is provided on a surface of an outer wall of the 21st holding frame 2b31, the surface being opposite a surface of the outer wall that faces the 22nd holding frame 2b32 in the y direction.

The 22nd holding frame 2b32 has a substantially-quadrangular-tubular shape that is open in an up-down direction.

The 22nd holding frame 2b32 is made of an insulator. Sides of the 22nd holding frame 2b32 hold the 12th S-phase resistor group 12b of the first resistance unit 10, the 22nd S-phase resistor group 22b of the second resistance unit 20, the 120th S-phase resistor group 120b of the 10th resistance unit 100, and the 220th S-phase resistor group 220b of the 20th resistance unit 200.

The 22nd holding frame 2b32 is held by the second S-phase-cooling unit 82b in the lower section, through an insulator or the like.

Provided at a lower portion of the 22nd holding frame 2b32, between an outer wall of the 22nd holding frame 2b32 and an inner wall of the 22nd accommodating region 2b2 is the second S-phase transmission unit a2s. That is, the second S-phase transmission unit a2s is provided on a surface of an outer wall of the 22nd holding frame 2b32, the surface being opposite a surface of the outer wall that faces the 21st holding frame 2b31 in the y direction.

Provided at an upper portion of the 22nd holding frame 2b32, between an inner wall of the 22nd accommodating region 2b2 and an outer wall of the 22nd holding frame 2b32, the outer wall having a positional relationship that the outer wall and the second S-phase transmission unit a2s sandwich the 22nd holding frame 2b32 in the y direction when viewed from above, is the second S-phase receipt unit b2s. That is, the second S-phase receipt unit b2s is provided on a surface of an outer wall of the 22nd holding frame 2b32, the surface facing the 21st holding frame 2b31 in the y direction.

The third accommodating region (T-phase-resistor-group-accommodating region) 2c has the 31st accommodating region 2c1 and the 32nd accommodating region 2c2.

The 32nd accommodating region 2c2 is provided to the left of the 31st accommodating region 2c1 in the y direction.

The 31st accommodating region (first T-phase-resistor-group-accommodating region) 2c1 accommodates a 31st holding frame 2c31 in the upper section, and accommodates a first T-phase-cooling unit 81c of the cooling unit 80 in the lower section.

The 32nd accommodating region (second T-phase-resistor-group-accommodating region) 2c2 accommodates a 32nd holding frame 2c32 in the upper section, and accommodates a second T-phase-cooling unit 82c of the cooling unit 80 in the lower section.

Provided at a lower portion of the 31st accommodating region 2c1 is a first T-phase air inlet 2c11 (not illustrated).

Provided at a lower portion of the 32nd accommodating region 2c2 is a second T-phase air inlet 2c12.

Provided at an upper portion of the 31st accommodating region 2c1 is a first T-phase air outlet 2c21.

Provided at an upper portion of the 32nd accommodating region 2c2 is a second T-phase air outlet 2c22.

Air taken in through the first T-phase air inlet 2c11 by the first T-phase-cooling unit 81c of the cooling unit 80 cools a 210th T-phase resistor group 210c, a 110th T-phase resistor group 110c, a 21st T-phase resistor group 21c, and an 11th T-phase resistor group 11c, and is discharged through the first T-phase air outlet 2c21.

Air taken in through the second T-phase air inlet 2c12 by the second T-phase-cooling unit 82c of the cooling unit 80 cools a 220th T-phase resistor group 220c, a 120th T-phase resistor group 120c, a 22nd T-phase resistor group 22c, and a 12th T-phase resistor group 12c, and is discharged through the second T-phase air outlet 2c22.

The first T-phase air inlet 2c11, the second T-phase air inlet 2c12, the first T-phase air outlet 2c21, and the second T-phase air outlet 2c22 are provided with lids (the first T-phase air inlet lid 2c13, the second T-phase air inlet lid 2c14, the first T-phase air outlet lid 2c23, and the second T-phase air outlet lid 2c24), which close when the inlets and outlets are not used, that is, when a load test is not performed, and at a time of an inspection, which will be described later, of the load-testing apparatus 1. These lids (first T-phase air inlet lid 2c13, second T-phase air inlet lid 2c14, first T-phase air outlet lid 2c23, and second T-phase air outlet lid 2c24) may be electrically opened and closed on the basis of operation of the operation unit 91 or the like, or may be manually opened and closed by the user. However, these lids may be omitted.

Note that the first T-phase air inlet lid 2c13 faces the second T-phase air inlet lid 2c14 in the y direction, and is provided at a position invisible in FIG. 1.

Sides of the 31st accommodating region 2c1, sides of the 32nd accommodating region 2c2, the first T-phase air inlet lid 2c13, the second T-phase air inlet lid 2c14, the first T-phase air outlet lid 2c23, and the second T-phase air outlet lid 2c24 are configured by walls of metallic members, such as aluminum plates.

The 31st holding frame 2c31 has a substantially-quadrangular-tubular shape that is open in an up-down direction.

The 31st holding frame 2c31 is made of an insulator. Sides of the 31st holding frame 2c31 hold the 11th T-phase resistor group 11c of the first resistance unit 10, the 21st T-phase resistor group 21c of the second resistance unit 20, the 110th T-phase resistor group 110c of the 10th resistance unit 100, and the 210th T-phase resistor group 210c of the 20th resistance unit 200.

The 31st holding frame 2c31 is held by the first T-phase-cooling unit 81c in the lower section, through an insulator or the like.

Provided at a lower portion of the 31st holding frame 2c31, between an outer wall of the 31st holding frame 2c31 and an inner wall of the 31st accommodating region 2c1 is the first T-phase transmission unit a1t. That is, the first T-phase transmission unit a1t is provided on a surface of an outer wall of the 31st holding frame 2c31, the surface facing the 32nd holding frame 2c32 in the y direction.

Provided at an upper portion of the 31st holding frame 2c31, between an inner wall of the 31st accommodating region 2c1 and an outer wall of the 31st holding frame 2c31, the outer wall having a positional relationship that the outer wall and the first T-phase transmission unit a1t sandwich the 31st holding frame 2c31 in the y direction when viewed from above, is the first T-phase receipt unit b1t. That is, the first T-phase receipt unit b1t is provided on a surface of an outer wall of the 31st holding frame 2c31, the surface being opposite a surface of the outer wall that faces the 32nd holding frame 2c32 in the y direction.

The 32nd holding frame 2c32 has a substantially-quadrangular-tubular shape that is open in an up-down direction.

The 32nd holding frame 2c32 is made of an insulator. Sides of the 32nd holding frame 2c32 hold the 12th T-phase resistor group 12c of the first resistance unit 10, the 22nd T-phase resistor group 22c of the second resistance unit 20, the 120th T-phase resistor group 120c of the 10th resistance unit 100, and the 220th T-phase resistor group 220c of the 20th resistance unit 200.

The 32nd holding frame 2c32 is held by the second T-phase-cooling unit 82c in the lower section, through an insulator or the like.

Provided at a lower portion of the 32nd holding frame 2c32, between an outer wall of the 32nd holding frame 2c32 and an inner wall of the 32nd accommodating region 2c2 is the second T-phase transmission unit a2t. That is, the second T-phase transmission unit a2t is provided on a surface of an outer wall of the 32nd holding frame 2c32, the surface being opposite a surface of the outer wall that faces the 31st holding frame 2c31 in the y direction.

Provided at an upper portion of the 32nd holding frame 2c32, between an inner wall of the 32nd accommodating region 2c2 and an outer wall of the 32nd holding frame 2c32, the outer wall having a positional relationship that the outer wall and the second T-phase transmission unit a2t sandwich the 32nd holding frame 2c32 in the y direction when viewed from above, is the second T-phase receipt unit b2t. That is, the second T-phase receipt unit b2t is provided on a surface of an outer wall of the 32nd holding frame 2c32, the surface facing the 31st holding frame 2c31 in the y direction.

The 11th accommodating region 2a1, the 21st accommodating region 2b1, and the 31st accommodating region 2c1 are arranged in the x direction.

The 12th accommodating region 2a2, the 22nd accommodating region 2b2, and the 32nd accommodating region 2c2 are arranged in the x direction.

The 11th accommodating region 2a1 and the 12th accommodating region 2a2 may be configured integrally or separately.

The 21st accommodating region 2b1 and the 22nd accommodating region 2b2 may be configured integrally or separately.

The 31st accommodating region 2c1 and the 32nd accommodating region 2c2 may be configured integrally or separately.

The fourth accommodating region 2d accommodates the first main relay unit 5, the second main relay unit 6, the third main relay unit 7, the first fine-adjustment relay unit 8, the second fine-adjustment relay unit 9, a 13th relay unit 13 and a 15th relay unit 15 of the first resistance unit 10, a 23rd relay unit 23 and a 25th relay unit 25 of the second resistance unit 20, a 150th R-phase relay 150a, a 150th S-phase relay 150b, and a 150th T-phase relay 150c of the 10th resistance unit 100, a 250th R-phase relay 250a, a 250th S-phase relay 250b, and a 250th T-phase relay 250c of the 20th resistance unit 200, the operation unit 91, and the terminal unit 93.

The fifth accommodating region 2e accommodates a 14th relay unit 14 and the 14th grounding relay 14g of the first resistance unit 10, a 24th relay unit 24 and the 24th grounding relay 24g of the second resistance unit 20, a 140th R-phase relay 140a, a 140th S-phase relay 140b, a 140th T-phase relay 140c, and the 140th grounding relay 140g of the 10th resistance unit 100, a 240th R-phase relay 240a, a 240th S-phase relay 240b, a 240th T-phase relay 240c, and the 240th grounding relay 240g of the 20th resistance unit 200.

(First Main Relay Unit 5)

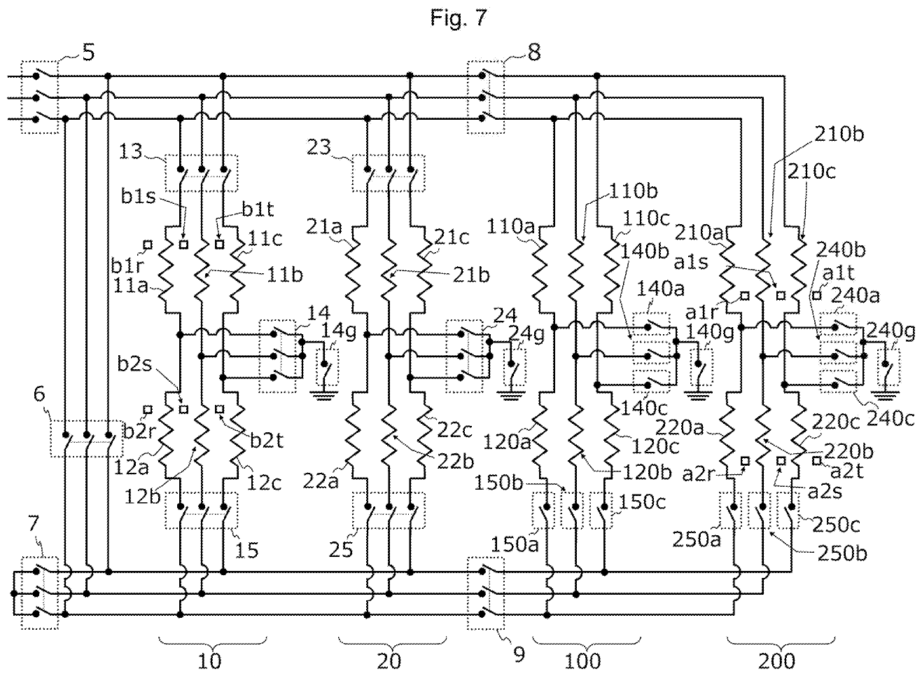

The first main relay unit 5 includes a vacuum circuit breaker (VCB), and is used to perform on/off-control of power supply from a test target power source to the first resistance unit 10, the second resistance unit 20, the 10th resistance unit 100, and the 20th resistance unit 200 (see FIG. 7).

One R-phase terminal of the first main relay unit 5 is connected to an R-phase terminal of the test target power source through the terminal unit 93.

The other R-phase terminal of the first main relay unit 5 is connected to one R-phase terminal of the second main relay unit 6, one R-phase terminal of the first fine-adjustment relay unit 8, one R-phase terminal of the 13th relay unit 13, and one R-phase terminal of the 23rd relay unit 23.

One S-phase terminal of the first main relay unit 5 is connected to an S-phase terminal of the test target power source through the terminal unit 93.

The other S-phase terminal of the first main relay unit 5 is connected to one S-phase terminal of the second main relay unit 6, one S-phase terminal of the first fine-adjustment relay unit 8, one S-phase terminal of the 13th relay unit 13, and one S-phase terminal of the 23rd relay unit 23.

One T-phase terminal of the first main relay unit 5 is connected to a T-phase terminal of the test target power source through the terminal unit 93.

The other T-phase terminal of the first main relay unit 5 is connected to one T-phase terminal of the second main relay unit 6, one T-phase terminal of the first fine-adjustment relay unit 8, one T-phase terminal of the 13th relay unit 13, and one T-phase terminal of the 23rd relay unit 23.

(Second Main Relay Unit 6)

The second main relay unit 6 includes a triple electromagnetic contactor (vacuum circuit switch (VCS)). The second main relay unit 6 is used to connect, in parallel, resistor groups adjacent in the y direction, such as the 11th R-phase resistor group 11a and the 12th R-phase resistor group 12a.

One R-phase terminal of the second main relay unit 6 is connected to the other R-phase terminal of the first main relay unit 5, and the like.

The other R-phase terminal of the second main relay unit 6 is connected to one R-phase terminal of the third main relay unit 7, one R-phase terminal of the second fine-adjustment relay unit 9, one R-phase terminal of the 15th relay unit, and one R-phase terminal of the 25th relay unit.

One S-phase terminal of the second main relay unit 6 is connected to the other S-phase terminal of the first main relay unit 5, and the like.

The other S-phase terminal of the second main relay unit 6 is connected to one S-phase terminal of the third main relay unit 7, one S-phase terminal of the second fine-adjustment relay unit 9, one S-phase terminal of the 15th relay unit, and one S-phase terminal of the 25th relay unit.

One T-phase terminal of the second main relay unit 6 is connected to the other T-phase terminal of the first main relay unit 5, and the like.

The other T-phase terminal of the second main relay unit 6 is connected to one T-phase terminal of the third main relay unit 7, one T-phase terminal of the second fine-adjustment relay unit 9, one T-phase terminal of the 15th relay unit, and one T-phase terminal of the 25th relay unit.

(Third Main Relay Unit 7)

The third main relay unit 7 includes a triple electromagnetic contactor (vacuum circuit switch (VCS)). The third main relay unit 7 is used for neutral-point connection when resistor groups adjacent in the y direction, such as the 11th R-phase resistor group 11a and the 12th R-phase resistor group 12a, are connected in series.

One R-phase terminal of the third main relay unit 7 is connected to the other R-phase terminal of the second main relay unit 6, and the like.

One S-phase terminal of the third main relay unit 7 is connected to the other S-phase terminal of the second main relay unit 6, and the like.

One T-phase terminal of the third main relay unit 7 is connected to the other T-phase terminal of the second main relay unit 6, and the like.

The other R-phase terminal of the third main relay unit 7, the other S-phase terminal of the third main relay unit 7, and the other T-phase terminal of the third main relay unit 7 are short-circuited.

(Interlocking Switching Control of Second Main Relay Unit 6 and Third Main Relay Unit 7)

It is necessary to prevent power from the test target power source from being supplied to the third main relay unit 7 through the second main relay unit 6. Therefore, it is desirable to perform a control to enable switching of the third main relay unit 7 to the on state, only when the second main relay unit 6 is in the off state (disenable switching of the third main relay unit 7 to the on state when the second main relay unit 6 is in the on state). In addition, before switching of the third main relay unit 7 to the on state is performed, a control may be performed to turn the second main relay unit 6 into the off state.

(First Fine-Adjustment Relay Unit 8 and Second Fine-Adjustment Relay Unit 9)

The first fine-adjustment relay unit 8 and the second fine-adjustment relay unit 9 include a triple electromagnetic contactor (vacuum circuit switch (VCS)). The first fine-adjustment relay unit 8 and the second fine-adjustment relay unit 9 are used to perform fine adjustment of the load amount, that is, to perform on/off-control of power supply from the test target power source to the 10th resistance unit 100 and the 20th resistance unit 200.

One R-phase terminal of the first fine-adjustment relay unit 8 is connected to the other R-phase terminal of the first main relay unit 5, and the like.

The other R-phase terminal of the first fine-adjustment relay unit 8 is connected to the other terminal of the 110th R-phase resistor group 110a and the other terminal of the 210th R-phase resistor group 210a. Note that one terminal of the 110th R-phase resistor group 110a is connected to one terminal of the 120th R-phase resistor group 120a.

One S-phase terminal of the first fine-adjustment relay unit 8 is connected to the other S-phase terminal of the first main relay unit 5, and the like.

The other S-phase terminal of the first fine-adjustment relay unit 8 is connected to the other terminal of the 110th S-phase resistor group 110b and the other terminal of the 210th S-phase resistor group 210b. Note that one terminal of the 110th S-phase resistor group 110b is connected to one terminal of the 120th S-phase resistor group 120b.

One T-phase terminal of the first fine-adjustment relay unit 8 is connected to the other T-phase terminal of the first main relay unit 5, and the like.

The other T-phase terminal of the first fine-adjustment relay unit 8 is connected to the other terminal of the 110th T-phase resistor group 110c and the other terminal of the 210th T-phase resistor group 210c. Note that one terminal of the 110th T-phase resistor group 110c is connected to one terminal of the 120th T-phase resistor group 120c.

One R-phase terminal of the second fine-adjustment relay unit 9 is connected to the other R-phase terminal of the second main relay unit 6, and the like.

The other R-phase terminal of the second fine-adjustment relay unit 9 is connected to one terminal of the 150th R-phase relay 150a and one terminal of the 250th R-phase relay 250a.

One S-phase terminal of the second fine-adjustment relay unit 9 is connected to the other S-phase terminal of the second main relay unit 6, and the like.

The other S-phase terminal of the second fine-adjustment relay unit 9 is connected to one terminal of the 150th S-phase relay 150b and one terminal of the 250th S-phase relay 250b.

One T-phase terminal of the second fine-adjustment relay unit 9 is connected to the other T-phase terminal of the second main relay unit 6, and the like.

The other T-phase terminal of the second fine-adjustment relay unit 9 is connected to one terminal of the 150th T-phase relay 150c and one terminal of the 250th T-phase relay 250c.

Next, the configurations of the first resistance unit 10, the second resistance unit 20, the 10th resistance unit 100, and the 20th resistance unit 200 will be described.

The first resistance unit 10 and the second resistance unit 20 are used as main loads in a load test.

The 10th resistance unit 100 and the 20th resistance unit 200 are used for fine adjustment of a load amount in the load test.

Used as the resistor groups of the 10th resistance unit 100 and the 20th resistance unit 200 are resistor groups having smaller capacitance than the capacitance of the resistor groups of the first resistance unit 10 and the second resistance unit 20.

(First Resistance Unit 10)

The first resistance unit 10 includes the 11th R-phase resistor group 11a, the 11th S-phase resistor group 11b, the 11th T-phase resistor group 11c, the 12th R-phase resistor group 12a, the 12th S-phase resistor group 12b, the 12th T-phase resistor group 12c, and a first switch group (the 13th relay unit 13, the 14th relay unit 14, the 14th grounding relay 14g, and the 15th relay unit 15).

The 11th R-phase resistor group 11a includes a resistor row in which a plurality of rod-shaped resistors R parallel to the x direction is arranged at predetermined intervals in the y direction.

The 12th R-phase resistor group 12a includes a resistor row in which a plurality of rod-shaped resistors R parallel to the x direction is arranged at predetermined intervals in the y direction.

The 12th R-phase resistor group 12a is provided to the left of the 11th R-phase resistor group 11a in the y direction.

One terminal of the 11th R-phase resistor group 11a is connected to one terminal of the 12th R-phase resistor group 12a.

The 11th R-phase resistor group 11a and the 12th R-phase resistor group 12a are used to perform an R-phase load test of a test target power source, such as a three-phase alternating-current generator, connected through the first main relay unit 5, the second main relay unit 6, the third main relay unit 7, and the first switch group.

The 11th R-phase resistor group 11a and the 12th R-phase resistor group 12a are connected in a state where series and parallel can be switched depending on the operation states of the second main relay unit 6, the third main relay unit 7, and the 14th relay unit 14.

For a load test, the resistors R, as pseudo-loads, of the 11th R-phase resistor group 11a and the 12th R-phase resistor group 12a receive power supply from a test target power source to generate heat.

In the first embodiment, an example in which the 11th R-phase resistor group 11a and the 12th R-phase resistor group 12a each include the plurality of resistors R is shown. However, the 11th R-phase resistor group 11a and the 12th R-phase resistor group 12a each may consist of one resistor R.

For example, when the third main relay unit 7 is turned into the on state and the second main relay unit 6 and the 14th relay unit 14 are turned into the off state, the 11th R-phase resistor group 11a and the 12th R-phase resistor group 12a are connected in series.

Alternatively, when the third main relay unit 7 is turned into the off state and the second main relay unit 6 and the 14th relay unit 14 are turned into the on state, the 11th R-phase resistor group 11a and the 12th R-phase resistor group 12a are connected in parallel.

The 11th S-phase resistor group 11b includes a resistor row in which a plurality of rod-shaped resistors R parallel to the x direction is arranged at predetermined intervals in the y direction.

The 12th S-phase resistor group 12b includes a resistor row in which a plurality of rod-shaped resistors R parallel to the x direction is arranged at predetermined intervals in the y direction.

The 12th S-phase resistor group 12b is provided to the left of the 11th S-phase resistor group 11b in the y direction.

One terminal of the 11th S-phase resistor group 11b is connected to one terminal of the 12th S-phase resistor group 12b.

The 11th S-phase resistor group 11b is located behind the 11th R-phase resistor group 11a in the x direction.

The 12th S-phase resistor group 12b is located behind the 12th R-phase resistor group 12a in the x direction.

The 11th S-phase resistor group 11b and the 12th S-phase resistor group 12b are used to perform an S-phase load test of a test target power source, such as a three-phase alternating-current generator, connected through the first main relay unit 5, the second main relay unit 6, the third main relay unit 7, and the first switch group.

The 11th S-phase resistor group 11b and the 12th S-phase resistor group 12b are connected in a state where series and parallel can be switched depending on the operation states of the second main relay unit 6, the third main relay unit 7, and the 14th relay unit 14.

For a load test, the resistors R, as pseudo-loads, of the 11th S-phase resistor group 11b and the 12th S-phase resistor group 12b receive power supply from a test target power source to generate heat.

In the first embodiment, an example in which the 11th S-phase resistor group 11b and the 12th S-phase resistor group 12b each include the plurality of resistors R is shown. However, the 11th S-phase resistor group 11b and the 12th S-phase resistor group 12b each may consist of one resistor R.

For example, when the third main relay unit 7 is turned into the on state and the second main relay unit 6 and the 14th relay unit 14 are turned into the off state, the 11th S-phase resistor group 11b and the 12th S-phase resistor group 12b are connected in series.

Alternatively, when the third main relay unit 7 is turned into the off state and the second main relay unit 6 and the 14th relay unit 14 are turned into the on state, the 11th S-phase resistor group 11b and the 12th S-phase resistor group 12b are connected in parallel.

The 11th T-phase resistor group 11c includes a resistor row in which a plurality of rod-shaped resistors R parallel to the x direction is arranged at predetermined intervals in the y direction.

The 12th T-phase resistor group 12c includes a resistor row in which a plurality of rod-shaped resistors R parallel to the x direction is arranged at predetermined intervals in the y direction.

The 12th T-phase resistor group 12c is provided to the left of the 11th T-phase resistor group 11c in the y direction.

One terminal of the 11th T-phase resistor group 11c is connected to one terminal of the 12th T-phase resistor group 12c.

The 11th T-phase resistor group 11c is located behind the 11th S-phase resistor group 11b in the x direction.

The 12th T-phase resistor group 12c is located behind the 12th S-phase resistor group 12b in the x direction.

The 11th T-phase resistor group 11c and the 12th T-phase resistor group 12c are used to perform a T-phase load test of a test target power source, such as a three-phase alternating-current generator, connected through the first main relay unit 5, the second main relay unit 6, the third main relay unit 7, and the first switch group.

The 11th T-phase resistor group 11c and the 12th T-phase resistor group 12c are connected in a state where series and parallel can be switched depending on the operation states of the second main relay unit 6, the third main relay unit 7, and the 14th relay unit 14.

For a load test, the resistors R, as pseudo-loads, of the 11th T-phase resistor group 11c and the 12th T-phase resistor group 12c receive power supply from a test target power source to generate heat.

In the first embodiment, an example in which the 11th T-phase resistor group 11c and the 12th T-phase resistor group 12c each include the plurality of resistors R is shown. However, the 11th T-phase resistor group 11c and the 12th T-phase resistor group 12c each may consist of one resistor R.

For example, when the third main relay unit 7 is turned into the on state and the second main relay unit 6 and the 14th relay unit 14 are turned into the off state, the 11th T-phase resistor group 11c and the 12th T-phase resistor group 12c are connected in series.

Alternatively, when the third main relay unit 7 is turned into the off state and the second main relay unit 6 and the 14th relay unit 14 are turned into the on state, the 11th T-phase resistor group 11c and the 12th T-phase resistor group 12c are connected in parallel.

In the first embodiment, the resistors R of the 11th R-phase resistor group 11a, the 12th R-phase resistor group 12a, the 11th S-phase resistor group 11b, the 12th S-phase resistor group 12b, the 11th T-phase resistor group 11c, and the 12th T-phase resistor group 12c extend in the x direction (first direction). The resistors R of the 11th R-phase resistor group 11a and the 12th R-phase resistor group 12a are arranged in the y direction (second direction). The resistors R of the 11th S-phase resistor group 11b and the 12th S-phase resistor group 12b are arranged in the y direction (second direction). The resistors R of the 11th T-phase resistor group 11c and the 12th T-phase resistor group 12c are arranged in the y direction (second direction).

However, the resistors R of the 11th R-phase resistor group 11a, the 12th R-phase resistor group 12a, the 11th S-phase resistor group 11b, the 12th S-phase resistor group 12b, the 11th T-phase resistor group 11c, and the 12th T-phase resistor group 12c may extend in the y direction (second direction). In this case, the resistors R of the 11th R-phase resistor group 11a and the 12th R-phase resistor group 12a are arranged in the x direction (first direction). The resistors R of the 11th S-phase resistor group 11b and the 12th S-phase resistor group 12b are arranged in the x direction (first direction). The resistors R of the 11th T-phase resistor group 11c and the 12th T-phase resistor group 12c are arranged in the x direction (first direction).

The 13th relay unit 13 and the 15th relay unit 15 include a triple electromagnetic contactor (vacuum circuit switch (VCS)). The 13th relay unit 13 and the 15th relay unit are used to perform on/off-control of power supply from the first main relay unit 5 to the 11th R-phase resistor group 11a, the 11th S-phase resistor group 11b, the 11th T-phase resistor group 11c, the 12th R-phase resistor group 12a, the 12th S-phase resistor group 12b, and the 12th T-phase resistor group 12c.

One R-phase terminal of the 13th relay unit 13 is connected to the other R-phase terminal of the first main relay unit 5, and the like.

The other R-phase terminal of the 13th relay unit 13 is connected to the other terminal of the 11th R-phase resistor group 11a.

One S-phase terminal of the 13th relay unit 13 is connected to the other S-phase terminal of the first main relay unit 5, and the like.

The other S-phase terminal of the 13th relay unit 13 is connected to the other terminal of the 11th S-phase resistor group 11b.

One T-phase terminal of the 13th relay unit 13 is connected to the other T-phase terminal of the first main relay unit 5, and the like.

The other T-phase terminal of the 13th relay unit 13 is connected to the other terminal of the 11th T-phase resistor group 11c.

One R-phase terminal of the 15th relay unit 15 is connected to the other R-phase terminal of the second main relay unit 6, and the like.

The other R-phase terminal of the 15th relay unit 15 is connected to the other terminal of the 12th R-phase resistor group 12a.

One S-phase terminal of the 15th relay unit 15 is connected to the other S-phase terminal of the second main relay unit 6, and the like.

The other S-phase terminal of the 15th relay unit 15 is connected to the other terminal of the 12th S-phase resistor group 12b.

One T-phase terminal of the 15th relay unit 15 is connected to the other T-phase terminal of the second main relay unit 6, and the like.

The other T-phase terminal of the 15th relay unit 15 is connected to the other terminal of the 12th T-phase resistor group 12c.

The 14th relay unit 14 includes a triple electromagnetic contactor (vacuum circuit switch (VCS)). The 14th relay unit 14 is used for neutral-point connection when the 11th R-phase resistor group 11a and the 12th R-phase resistor group 12a are connected in parallel, the 11th S-phase resistor group 11b and the 12th S-phase resistor group 12b are connected in parallel, and the 11th T-phase resistor group 11c and the 12th T-phase resistor group 12c are connected in parallel.

That is, the 14th relay unit 14 is used to perform on/off-control of short-circuiting of one terminal of the 11th R-phase resistor group 11a, one terminal of the 11th S-phase resistor group 11b, and one terminal of the 11th T-phase resistor group 11c.

One R-phase terminal of the 14th relay unit 14 is connected to one terminal of the 11th R-phase resistor group 11a and one terminal of the 12th R-phase resistor group 12a.

One S-phase terminal of the 14th relay unit 14 is connected to one terminal of the 11th S-phase resistor group 11b and one terminal of the 12th S-phase resistor group 12b.

One T-phase terminal of the 14th relay unit 14 is connected to one terminal of the 11th T-phase resistor group 11c and one terminal of the 12th T-phase resistor group 12c.

The other R-phase terminal of the 14th relay unit 14, the other S-phase terminal of the 14th relay unit 14, and the other T-phase terminal of the 14th relay unit 14 are short-circuited.

At a time of an inspection, which will be described later, of the load-testing apparatus 1, the 14th grounding relay 14g is used to ground the 11th R-phase resistor group 11a, the 12th R-phase resistor group 12a, the 11th S-phase resistor group 11b, the 12th S-phase resistor group 12b, the 11th T-phase resistor group 11c, and the 12th T-phase resistor group 12c (to perform on/off-switching of the grounding).

One terminal of the 14th grounding relay 14g is connected to the other R-phase terminal of the 14th relay unit 14, the other S-phase terminal of the 14th relay unit 14, and the other T-phase terminal of the 14th relay unit 14, that is, the short-circuit-side terminals of the 14th relay unit 14.

The other terminal of the 14th grounding relay 14g is connected to the grounded surface.

It is desirable that cables connecting the relays accommodated in the fourth accommodating region 2d (such as the 13th relay unit 13), to the resistor groups accommodated in the 11th accommodating region 2a1, the 21st accommodating region 2b1, and the 31st accommodating region 2c1 (such as the 11th T-phase resistor group 11c) are provided closer to the outside than said resistor groups are, on the opposite side of a region including the 12th accommodating region 2a2, the 22nd accommodating region 2b2, and the 32nd accommodating region 2c2 when they are seen in the z direction.

It is desirable that cables connecting the relays accommodated in the fourth accommodating region 2d (such as the 15th relay unit 15), to the resistor groups accommodated in the 12th accommodating region 2a2, the 22nd accommodating region 2b2, and the 32nd accommodating region 2c2 (such as the 12th T-phase resistor group 12c) are provided closer to the outside than said resistor groups are, on the opposite side of a region including the 11th accommodating region 2a1, the 21st accommodating region 2b1, and the 31st accommodating region 2c1 when they are seen in the z direction.

It is desirable that cables connecting the relays accommodated in the fifth accommodating region 2e (such as the 14th relay unit 14), to the resistor groups accommodated in the 11th accommodating region 2a1, the 21st accommodating region 2b1, the 31st accommodating region 2c1, the 12th accommodating region 2a2, the 22nd accommodating region 2b2, and the 32nd accommodating region 2c2 (such as the 11th R-phase resistor group 11a) are provided between the resistor groups on the y-direction right side (such as the 11th T-phase resistor group 11c) and the resistor groups on the y-direction left side (such as the 12th T-phase resistor group 12c) when they are seen in the z direction.

For example, the wiring is performed such that a cable connecting the other S-phase terminal of the 13th relay unit 13 to the other terminal of the 11th S-phase resistor group 11b, and a cable connecting the other T-phase terminal of the 13th relay unit 13 to the other terminal of the 11th T-phase resistor group 11c are located in the 11th accommodating region 2a1, outside a region of the 11th accommodating region 2a1 where there are the resistor groups, on the opposite side of a region where there is the 12th accommodating region 2a2, when they are seen in the z direction.

The wiring is performed such that a cable connecting the other T-phase terminal of the 13th relay unit 13 to the other terminal of the 11th T-phase resistor group 11c is located in the 21st accommodating region 2b1, outside a region of the 21st accommodating region 2b1 where there are the resistor groups, on the opposite side of a region where there is the 22nd accommodating region 2b2, when they are seen in the z direction.

The wiring is performed such that a cable connecting the other S-phase terminal of the 15th relay unit 15 to the other terminal of the 12th S-phase resistor group 12b, and a cable connecting the other T-phase terminal of the 15th relay unit 15 to the other terminal of the 12th T-phase resistor group 12c are located in the 12th accommodating region 2a2, outside a region of the 12th accommodating region 2a2 where there are the resistor groups, on the opposite side of a region where there is the 11th accommodating region 2a1, when they are seen in the z direction.

The wiring is performed such that a cable connecting the other T-phase terminal of the 15th relay unit 15 to the other terminal of the 12th T-phase resistor group 12c is located in the 22nd accommodating region 2b2, outside a region of the 22nd accommodating region 2b2 where there are the resistor groups, on the opposite side of a region where there is the 21st accommodating region 2b1, when they are seen in the z direction.

The wiring is performed such that a cable connecting one R-phase terminal of the 14th relay unit 14 to one terminal of the 11th R-phase resistor group 11a and one terminal of the 12th R-phase resistor group 12a is located between a region of the 21st accommodating region 2b1 where there are the resistor groups and a region of the 22nd accommodating region 2b2 where there are the resistor groups, when they are seen in the z direction.

The wiring is performed such that a cable connecting one R-phase terminal of the 14th relay unit 14 to one terminal of the 11th R-phase resistor group 11a and one terminal of the 12th R-phase resistor group 12a, and a cable connecting one S-phase terminal of the 14th relay unit 14 to one terminal of the 11th S-phase resistor group 11b and one terminal of the 12th S-phase resistor group 12b are located between a region of the 31st accommodating region 2c1 where there are the resistor groups and a region of the 32nd accommodating region 2c2 where there are the resistor groups, when they are seen in the z direction.

Consequently, it is possible to use the spaces between the resistor groups adjacent in the y direction to efficiently perform the wiring to the short-circuiting switches (such as the 14th relay unit 14) accommodated in the fifth accommodating region 2e.

In the first embodiment, the 11th R-phase resistor group 11a, the 11th S-phase resistor group 11b, the 11th T-phase resistor group 11c, the 12th R-phase resistor group 12a, the 12th S-phase resistor group 12b, and the 12th T-phase resistor group 12c each include one layer of resistor row. The one layer of resistor row is arranged in the z direction. The resistor row includes seven resistors R arranged in the y direction and connected in series. However, the number of resistors R arranged in each resistor row, and the number of stacked layers of resistor row are not limited thereto. In addition, the resistors R of said resistor row may be connected in parallel.

(Second Resistance Unit 20)

The second resistance unit 20 includes the 21st R-phase resistor group 21a, the 21st S-phase resistor group 21b, the 21st T-phase resistor group 21c, the 22nd R-phase resistor group 22a, the 22nd S-phase resistor group 22b, the 22nd T-phase resistor group 22c, and a second switch group (the 23rd relay unit 23, the 24th relay unit 24, the 24th grounding relay 24g, and the 25th relay unit 25).

The configuration of the 21st R-phase resistor group 21a of the second resistance unit 20 is similar to the configuration of the 11th R-phase resistor group 11a of the first resistance unit 10.

The configuration of the 21st S-phase resistor group 21b of the second resistance unit 20 is similar to the configuration of the 11th S-phase resistor group 11b of the first resistance unit 10.

The configuration of the 21st T-phase resistor group 21c of the second resistance unit 20 is similar to the configuration of the 11th T-phase resistor group 11c of the first resistance unit 10.

The configuration of the 23rd relay unit 23 of the second resistance unit 20 is similar to the configuration of the 13th relay unit 13 of the first resistance unit 10.

The configuration of the 24th relay unit 24 of the second resistance unit 20 is similar to the configuration of the 14th relay unit 14 of the first resistance unit 10.

The configuration of the 24th grounding relay 24g of the second resistance unit 20 is similar to the configuration of the 14th grounding relay 14g of the first resistance unit 10.

The configuration of the 25th relay unit 25 of the second resistance unit 20 is similar to the configuration of the 15th relay unit 15 of the first resistance unit 10.

(10th Resistance Unit 100)

The 10th resistance unit 100 includes the 110th R-phase resistor group 110a, the 110th S-phase resistor group 110b, the 110th T-phase resistor group 110c, the 120th R-phase resistor group 120a, the 120th S-phase resistor group 120b, the 120th T-phase resistor group 120c, and a 10th switch group (the 140th R-phase relay 140a, the 140th S-phase relay 140b, the 140th T-phase relay 140c, the 140th grounding relay 140g, the 150th R-phase relay 150a, the 150th S-phase relay 150b, and the 150th T-phase relay 150c).

The 110th R-phase resistor group 110a includes a resistor row in which a plurality of rod-shaped resistors R parallel to the x direction is arranged at predetermined intervals in the y direction.

The 120th R-phase resistor group 120a includes a resistor row in which a plurality of rod-shaped resistors R parallel to the x direction is arranged at predetermined intervals in the y direction.

The 120th R-phase resistor group 120a is provided to the left of the 110th R-phase resistor group 110a in the y direction.

The 110th R-phase resistor group 110a and the 120th R-phase resistor group 120a are used to perform an R-phase load test of a test target power source, such as a three-phase alternating-current generator, connected through the first main relay unit 5, the second main relay unit 6, the third main relay unit 7, the first fine-adjustment relay unit 8, the second fine-adjustment relay unit 9, and the 10th switch group.

The 110th R-phase resistor group 110a and the 120th R-phase resistor group 120a are connected in a state where series and parallel can be switched depending on the operation states of the second main relay unit 6, the third main relay unit 7, the 140th R-phase relay 140a, the 140th S-phase relay 140b, and the 140th T-phase relay 140c.

For a load test, the resistors R, as pseudo-loads, of the 110th R-phase resistor group 110a and the 120th R-phase resistor group 120a receive power supply from a test target power source to generate heat.

In the first embodiment, an example in which the 110th R-phase resistor group 110a and the 120th R-phase resistor group 120a each include the plurality of resistors R is shown. However, the 110th R-phase resistor group 110a and the 120th R-phase resistor group 120a each may consist of one resistor R.

For example, when the third main relay unit 7 is turned into the on state and the second main relay unit 6, the 140th R-phase relay 140a, the 140th S-phase relay 140b, and the 140th T-phase relay 140c are turned into the off state, the 110th R-phase resistor group 110a and the 120th R-phase resistor group 120a are connected in series.

Alternatively, when the third main relay unit 7 is turned into the off state and the second main relay unit 6, the 140th R-phase relay 140a, the 140th S-phase relay 140b, and the 140th T-phase relay 140c are turned into the on state, the 110th R-phase resistor group 110a and the 120th R-phase resistor group 120a are connected in parallel.

The 110th S-phase resistor group 110b includes a resistor row in which a plurality of rod-shaped resistors R parallel to the x direction is arranged at predetermined intervals in the y direction.

The 120th S-phase resistor group 120b includes a resistor row in which a plurality of rod-shaped resistors R parallel to the x direction is arranged at predetermined intervals in the y direction.

The 120th S-phase resistor group 120b is provided to the left of the 110th S-phase resistor group 110b in the y direction.

The 110th S-phase resistor group 110b is located behind the 110th R-phase resistor group 110a in the x direction.

The 120th S-phase resistor group 120b is located behind the 120th R-phase resistor group 120a in the x direction.

The 110th S-phase resistor group 110b and the 120th S-phase resistor group 120b are used to perform an S-phase load test of a test target power source, such as a three-phase alternating-current generator, connected through the first main relay unit 5, the second main relay unit 6, the third main relay unit 7, the first fine-adjustment relay unit 8, the second fine-adjustment relay unit 9, and the 10th switch group.

The 110th S-phase resistor group 110b and the 120th S-phase resistor group 120b are connected in a state where series and parallel can be switched depending on the operation states of the second main relay unit 6, the third main relay unit 7, the 140th R-phase relay 140a, the 140th S-phase relay 140b, and the 140th T-phase relay 140c.

For a load test, the resistors R, as pseudo-loads, of the 110th S-phase resistor group 110b and the 120th S-phase resistor group 120b receive power supply from a test target power source to generate heat.

In the first embodiment, an example in which the 110th S-phase resistor group 110b and the 120th S-phase resistor group 120b each include the plurality of resistors R is shown. However, the 110th S-phase resistor group 110b and the 120th S-phase resistor group 120b each may consist of one resistor R.

For example, when the third main relay unit 7 is turned into the on state and the second main relay unit 6, the 140th R-phase relay 140a, the 140th S-phase relay 140b, and the 140th T-phase relay 140c are turned into the off state, the 110th S-phase resistor group 110b and the 120th S-phase resistor group 120b are connected in series.

Alternatively, when the third main relay unit 7 is turned into the off state and the second main relay unit 6, the 140th R-phase relay 140a, the 140th S-phase relay 140b, and the 140th T-phase relay 140c are turned into the on state, the 110th S-phase resistor group 110b and the 120th S-phase resistor group 120b are connected in parallel.

The 110th T-phase resistor group 110c includes a resistor row in which a plurality of rod-shaped resistors R parallel to the x direction is arranged at predetermined intervals in the y direction.

The 120th T-phase resistor group 120c includes a resistor row in which a plurality of rod-shaped resistors R parallel to the x direction is arranged at predetermined intervals in the y direction.

The 120th T-phase resistor group 120c is provided to the left of the 110th T-phase resistor group 110c in the y direction.

The 110th T-phase resistor group 110c is located behind the 110th S-phase resistor group 110b in the x direction.

The 120th T-phase resistor group 120c is located behind the 120th S-phase resistor group 120b in the x direction.

The 110th T-phase resistor group 110c and the 120th T-phase resistor group 120c are used to perform a T-phase load test of a test target power source, such as a three-phase alternating-current generator, connected through the first main relay unit 5, the second main relay unit 6, the third main relay unit 7, the first fine-adjustment relay unit 8, the second fine-adjustment relay unit 9, and the 10th switch group.

The 110th T-phase resistor group 110c and the 120th T-phase resistor group 120c are connected in a state where series and parallel can be switched depending on the operation states of the second main relay unit 6, the third main relay unit 7, the 140th R-phase relay 140a, the 140th S-phase relay 140b, and the 140th T-phase relay 140c.

For a load test, the resistors R, as pseudo-loads, of the 110th T-phase resistor group 110c and the 120th T-phase resistor group 120c receive power supply from a test target power source to generate heat.

In the first embodiment, an example in which the 110th T-phase resistor group 110c and the 120th T-phase resistor group 120c each include the plurality of resistors R is shown. However, the 110th T-phase resistor group 110c and the 120th T-phase resistor group 120c each may consist of one resistor R.

For example, when the third main relay unit 7 is turned into the on state and the second main relay unit 6, the 140th R-phase relay 140a, the 140th S-phase relay 140b, and the 140th T-phase relay 140c are turned into the off state, the 110th T-phase resistor group 110c and the 120th T-phase resistor group 120c are connected in series.

Alternatively, when the third main relay unit 7 is turned into the off state and the second main relay unit 6, the 140th R-phase relay 140a, the 140th S-phase relay 140b, and the 140th T-phase relay 140c are turned into the on state, the 110th T-phase resistor group 110c and the 120th T-phase resistor group 120c are connected in parallel.

In the first embodiment, the resistors R of the 110th R-phase resistor group 110a, the 120th R-phase resistor group 120a, the 110th S-phase resistor group 110b, the 120th S-phase resistor group 120b, the 110th T-phase resistor group 110c, and the 120th T-phase resistor group 120c extend in the x direction (first direction). The resistors R of the 110th R-phase resistor group 110a and the 120th R-phase resistor group 120a are arranged in the y direction (second direction). The resistors R of the 110th S-phase resistor group 110b and the 120th S-phase resistor group 120b are arranged in the y direction (second direction). The resistors R of the 110th T-phase resistor group 110c and the 120th T-phase resistor group 120c are arranged in the y direction (second direction).

However, the resistors R of the 110th R-phase resistor group 110a, the 120th R-phase resistor group 120a, the 110th S-phase resistor group 110b, the 120th S-phase resistor group 120b, the 110th T-phase resistor group 110c, and the 120th T-phase resistor group 120c may extend in the y direction (second direction). In this case, the resistors R of the 110th R-phase resistor group 110a and the 120th R-phase resistor group 120a are arranged in the x direction (first direction). The resistors R of the 110th S-phase resistor group 110b and the 120th S-phase resistor group 120b are arranged in the x direction (first direction). The resistors R of the 110th T-phase resistor group 110c and the 120th T-phase resistor group 120c are arranged in the x direction (first direction).

The 150th R-phase relay 150a is used to perform on/off-control of power supply from the first main relay unit 5 to the 110th R-phase resistor group 110a and the 120th R-phase resistor group 120a.

One terminal of the 150th R-phase relay 150a is connected to the other R-phase terminal of the second fine-adjustment relay unit 9, and the like.

The other terminal of the 150th R-phase relay 150a is connected to the other terminal of the 120th R-phase resistor group 120a.

The 150th S-phase relay 150b is used to perform on/off-control of power supply from the first main relay unit 5 to the 110th S-phase resistor group 110b and the 120th S-phase resistor group 120b.

One terminal of the 150th S-phase relay 150b is connected to the other S-phase terminal of the second fine-adjustment relay unit 9, and the like.

The other terminal of the 150th S-phase relay 150b is connected to the other terminal of the 120th S-phase resistor group 120b.

The 150th T-phase relay 150c is used to perform on/off-control of power supply from the first main relay unit 5 to the 110th T-phase resistor group 110c and the 120th T-phase resistor group 120c.

One terminal of the 150th T-phase relay 150c is connected to the other T-phase terminal of the second fine-adjustment relay unit 9, and the like.

The other terminal of the 150th T-phase relay 150c is connected to the other terminal of the 120th T-phase resistor group 120c.

The 140th R-phase relay 140a, the 140th S-phase relay 140b, and the 140th T-phase relay 140c are used for neutral-point connection when the 110th R-phase resistor group 110a and the 120th R-phase resistor group 120a are connected in parallel, the 110th S-phase resistor group 110b and the 120th S-phase resistor group 120b are connected in parallel, and the 110th T-phase resistor group 110c and the 120th T-phase resistor group 120c are connected in parallel.

That is, the 140th R-phase relay 140a, the 140th S-phase relay 140b, and the 140th T-phase relay 140c are used to perform on/off-control of short-circuiting of one terminal of the 110th R-phase resistor group 110a, one terminal of the 110th S-phase resistor group 110b, and one terminal of the 110th T-phase resistor group 110c.

One terminal of the 140th R-phase relay 140a is connected to one terminal of the 110th R-phase resistor group 110a and one terminal of the 120th R-phase resistor group 120a.

One terminal of the 140th S-phase relay 140b is connected to one terminal of the 110th S-phase resistor group 110b and one terminal of the 120th S-phase resistor group 120b.

One terminal of the 140th T-phase relay 140c is connected to one terminal of the 110th T-phase resistor group 110c and one terminal of the 120th T-phase resistor group 120c.

The other terminal of the 140th R-phase relay 140a, the other terminal of the 140th S-phase relay 140b, and the other terminal of the 140th T-phase relay 140c are short-circuited.

At a time of an inspection, which will be described later, of the load-testing apparatus 1, the 140th grounding relay 140g is used to ground the 110th R-phase resistor group 110a, the 120th R-phase resistor group 120a, the 110th S-phase resistor group 110b, the 120th S-phase resistor group 120b, the 110th T-phase resistor group 110c, and the 120th T-phase resistor group 120c (to perform on/off-switching of the grounding).

One terminal of the 140th grounding relay 140g is connected to the other terminal (short-circuit-side terminal) of the 140th R-phase relay 140a, the other terminal (short-circuit-side terminal) of the 140th S-phase relay 140b, and the other terminal (short-circuit-side terminal) of the 140th T-phase relay 140c.

The other terminal of the 140th grounding relay 140g is connected to the grounded surface.

It is desirable that cables connecting the relays accommodated in the fourth accommodating region 2d (such as the first fine-adjustment relay unit 8), to the resistor groups accommodated in the 11th accommodating region 2a1, the 21st accommodating region 2b1, and the 31st accommodating region 2c1 (such as the 110th T-phase resistor group 110c) are provided closer to the outside than said resistor groups are, on the opposite side of a region including the 12th accommodating region 2a2, the 22nd accommodating region 2b2, and the 32nd accommodating region 2c2 when they are seen in the z direction.

It is desirable that cables connecting the relays accommodated in the fourth accommodating region 2d (such as the second fine-adjustment relay unit 9), to the resistor groups accommodated in the 12th accommodating region 2a2, the 22nd accommodating region 2b2, and the 32nd accommodating region 2c2 (such as the 120th T-phase resistor group 120c) are provided closer to the outside than said resistor groups are, on the opposite side of a region including the 11th accommodating region 2a1, the 21st accommodating region 2b1, and the 31st accommodating region 2c1 when they are seen in the z direction.

It is desirable that cables connecting the relays accommodated in the fifth accommodating region 2e (such as the 140th R-phase relay 140a), to the resistor groups accommodated in the 11th accommodating region 2a1, the 21st accommodating region 2b1, the 31st accommodating region 2c1, the 12th accommodating region 2a2, the 22nd accommodating region 2b2, and the 32nd accommodating region 2c2 (such as the 110th R-phase resistor group 110a) are provided between the resistor groups on the y-direction right side (such as the 110th T-phase resistor group 110c) and the resistor groups on the y-direction left side (such as the 120th T-phase resistor group 120c) when they are seen in the z direction.

For example, the wiring is performed such that a cable connecting the other S-phase terminal of the first fine-adjustment relay unit 8 to the other terminal of the 110th S-phase resistor group 110b, and a cable connecting the other T-phase terminal of the first fine-adjustment relay unit 8 to the other terminal of the 110th T-phase resistor group 110c are located in the 11th accommodating region 2a1, outside a region of the 11th accommodating region 2a1 where there are the resistor groups, on the opposite side of a region where there is the 12th accommodating region 2a2, when they are seen in the z direction.

The wiring is performed such that a cable connecting the other T-phase terminal of the first fine-adjustment relay unit 8 to the other terminal of the 110th T-phase resistor group 110c is located in the 21st accommodating region 2b1, outside a region of the 21st accommodating region 2b1 where there are the resistor groups, on the opposite side of a region where there is the 22nd accommodating region 2b2, when they are seen in the z direction.

The wiring is performed such that a cable connecting the other S-phase terminal of the second fine-adjustment relay unit 9 to the other terminal of the 120th S-phase resistor group 120b, and a cable connecting the other T-phase terminal of the second fine-adjustment relay unit 9 to the other terminal of the 120th T-phase resistor group 120c are located in the 12th accommodating region 2a2, outside a region of the 12th accommodating region 2a2 where there are the resistor groups, on the opposite side of a region where there is the 11th accommodating region 2a1, when they are seen in the z direction.

The wiring is performed such that a cable connecting the other T-phase terminal of the second fine-adjustment relay unit 9 to the other terminal of the 120th T-phase resistor group 120c is located in the 22nd accommodating region 2b2, outside a region of the 22nd accommodating region 2b2 where there are the resistor groups, on the opposite side of a region where there is the 21st accommodating region 2b1, when they are seen in the z direction.

The wiring is performed such that a cable connecting one terminal of the 140th R-phase relay 140a to one terminal of the 110th R-phase resistor group 110a and one terminal of the 120th R-phase resistor group 120a is located between a region of the 21st accommodating region 2b1 where there are the resistor groups and a region of the 22nd accommodating region 2b2 where there are the resistor groups, when they are seen in the z direction.

The wiring is performed such that a cable connecting one terminal of the 140th R-phase relay 140a to one terminal of the 110th R-phase resistor group 110a and one terminal of the 120th R-phase resistor group 120a, and a cable connecting one terminal of the 140th S-phase relay 140b to one terminal of the 110th S-phase resistor group 110b and one terminal of the 120th S-phase resistor group 120b are located between a region of the 31st accommodating region 2c1 where there are the resistor groups and a region of the 32nd accommodating region 2c2 where there are the resistor groups, when they are seen in the z direction.

Consequently, it is possible to use the spaces between the resistor groups adjacent in the y direction to efficiently perform the wiring to the short-circuiting switches (such as the 140th R-phase relay 140a) accommodated in the fifth accommodating region 2e.

In the first embodiment, the 110th R-phase resistor group 110a, the 110th S-phase resistor group 110b, the 110th T-phase resistor group 110c, the 120th R-phase resistor group 120a, the 120th S-phase resistor group 120b, and the 120th T-phase resistor group 120c each include one layer of resistor row. The one layer of resistor row is arranged in the z direction. The resistor row includes seven resistors R arranged in the y direction and connected in series. However, the number of resistors R arranged in each resistor row, and the number of stacked layers of resistor row are not limited thereto. In addition, the resistors R of said resistor row may be connected in parallel.

(20th Resistance Unit 200)

The 20th resistance unit 200 includes the 210th R-phase resistor group 210a, the 210th S-phase resistor group 210b, the 210th T-phase resistor group 210c, the 220th R-phase resistor group 220a, the 220th S-phase resistor group 220b, the 220th T-phase resistor group 220c, and a 20th switch group (the 240th R-phase relay 240a, the 240th S-phase relay 240b, the 240th T-phase relay 240c, the 240th grounding relay 240g, the 250th R-phase relay 250a, the 250th S-phase relay 250b, and the 250th T-phase relay 250c).

The configuration of the 210th R-phase resistor group 210a of the 20th resistance unit 200 is similar to the configuration of the 110th R-phase resistor group 110a of the 10th resistance unit 100.

The configuration of the 210th S-phase resistor group 210b of the 20th resistance unit 200 is similar to the configuration of the 110th S-phase resistor group 110b of the 10th resistance unit 100.

The configuration of the 210th T-phase resistor group 210c of the 20th resistance unit 200 is similar to the configuration of the 110th T-phase resistor group 110c of the 10th resistance unit 100.

The configuration of the 240th R-phase relay 240a of the 20th resistance unit 200 is similar to the configuration of the 140th R-phase relay 140a of the 10th resistance unit 100.

The configuration of the 240th S-phase relay 240b of the 20th resistance unit 200 is similar to the configuration of the 140th S-phase relay 140b of the 10th resistance unit 100.

The configuration of the 240th T-phase relay 240c of the 20th resistance unit 200 is similar to the configuration of the 140th T-phase relay 140c of the 10th resistance unit 100.

The configuration of the 240th grounding relay 240g of the 20th resistance unit 200 is similar to the configuration of the 140th grounding relay 140g of the 10th resistance unit 100.

The configuration of the 250th R-phase relay 250a of the 20th resistance unit 200 is similar to the configuration of the 150th R-phase relay 150a of the 10th resistance unit 100.

The configuration of the 250th S-phase relay 250b of the 20th resistance unit 200 is similar to the configuration of the 150th S-phase relay 150b of the 10th resistance unit 100.

The configuration of the 250th T-phase relay 250c of the 20th resistance unit 200 is similar to the configuration of the 150th T-phase relay 150c of the 10th resistance unit 100.

(Cooling Unit 80)

The cooling unit 80 includes the first R-phase-cooling unit 81a, the second R-phase-cooling unit 82a, the first S-phase-cooling unit 81b, the second S-phase-cooling unit 82b, the first T-phase-cooling unit 81c, and the second T-phase-cooling unit 82c.

The first R-phase-cooling unit 81a cools the 11th R-phase resistor group 11a, the 21st R-phase resistor group 21a, the 110th R-phase resistor group 110a, and the 210th R-phase resistor group 210a.

The second R-phase-cooling unit 82a cools the 12th R-phase resistor group 12a, the 22nd R-phase resistor group 22a, the 120th R-phase resistor group 120a, and the 220th R-phase resistor group 220a.

The first S-phase-cooling unit 81b cools the 11th S-phase resistor group 11b, the 21st S-phase resistor group 21b, the 110th S-phase resistor group 110b, and the 210th S-phase resistor group 210b.

The second S-phase-cooling unit 82b cools the 12th S-phase resistor group 12b, the 22nd S-phase resistor group 22b, the 120th S-phase resistor group 120b, and the 220th S-phase resistor group 220b.

The first T-phase-cooling unit 81c cools the 11th T-phase resistor group 11c, the 21st T-phase resistor group 21c, the 110th T-phase resistor group 110c, and the 210th T-phase resistor group 210c.

The second T-phase-cooling unit 82c cools the 12th T-phase resistor group 12c, the 22nd T-phase resistor group 22c, the 120th T-phase resistor group 120c, and the 220th T-phase resistor group 220c.

(Configuration of Transmission and Receipt Units)

Next, a transmission device and a receipt device, such as the first R-phase transmission unit a1r, used for inspection of the load-testing apparatus 1 will be described.

The first R-phase transmission unit a1r transmits a signal to the first R-phase receipt unit b1r.

The first R-phase receipt unit b1r receives the signal from the first R-phase transmission unit a1r.

On the basis of the received signal, the first R-phase receipt unit b1r transmits, to the operation unit 91, information regarding the radio-wave strength of the signal transmitted from the first R-phase transmission unit a1r.

The first R-phase transmission unit a1r and the first R-phase receipt unit b1r are disposed such that when viewed from above, the first R-phase transmission unit a1r and the first R-phase receipt unit b1r have a positional relationship that the first R-phase transmission unit a1r and the first R-phase receipt unit b1r sandwich the 11th holding frame 2a31, and the first R-phase transmission unit a1r and the first R-phase receipt unit b1r have a positional relationship that the first R-phase transmission unit a1r and the first R-phase receipt unit b1r sandwich the 11th R-phase resistor group 11a, the 21st R-phase resistor group 21a, the 110th R-phase resistor group 110a, and the 210th R-phase resistor group 210a.

In addition, when viewed from above, the first R-phase transmission unit a1r and the first R-phase receipt unit b1r have a positional relationship that the first R-phase transmission unit a1r and the first R-phase receipt unit b1r sandwich the 11th holding frame 2a31, and the first R-phase transmission unit a1r and the first R-phase receipt unit b1r are arranged in a direction (y direction) perpendicular to the direction (x direction) in which the resistors R of the 11th R-phase resistor group 11a, the 21st R-phase resistor group 21a, the 110th R-phase resistor group 110a, and the 210th R-phase resistor group 210a extend.

In addition, the first R-phase transmission unit a1r and the first R-phase receipt unit b1r are disposed such that one of the first R-phase transmission unit a1r and the first R-phase receipt unit b1r is located above, and the other is located below.

The first R-phase transmission unit a1r and the first R-phase receipt unit b1r are attached to an outer wall of the 11th holding frame 2a31 or an inner wall of the 11th accommodating region 2a1.

The second R-phase transmission unit a2r transmits a signal to the second R-phase receipt unit b2r.

The second R-phase receipt unit b2r receives the signal from the second R-phase transmission unit a2r.

On the basis of the received signal, the second R-phase receipt unit b2r transmits, to the operation unit 91, information regarding the radio-wave strength of the signal transmitted from the second R-phase transmission unit a2r.

The second R-phase transmission unit a2r and the second R-phase receipt unit b2r are disposed such that when viewed from above, the second R-phase transmission unit a2r and the second R-phase receipt unit b2r have a positional relationship that the second R-phase transmission unit a2r and the second R-phase receipt unit b2r sandwich the 12th holding frame 2a32, and the second R-phase transmission unit a2r and the second R-phase receipt unit b2r have a positional relationship that the second R-phase transmission unit a2r and the second R-phase receipt unit b2r sandwich the 12th R-phase resistor group 12a, the 22nd R-phase resistor group 22a, the 120th R-phase resistor group 120a, and the 220th R-phase resistor group 220a.

In addition, when viewed from above, the second R-phase transmission unit a2r and the second R-phase receipt unit b2r have a positional relationship that the second R-phase transmission unit a2r and the second R-phase receipt unit b2r sandwich the 12th holding frame 2a32, and the second R-phase transmission unit a2r and the second R-phase receipt unit b2r are arranged in a direction (y direction) perpendicular to the direction (x direction) in which the resistors R of the 12th R-phase resistor group 12a, the 22nd R-phase resistor group 22a, the 120th R-phase resistor group 120a, and the 220th R-phase resistor group 220a extend.

In addition, the second R-phase transmission unit a2r and the second R-phase receipt unit b2r are disposed such that one of the second R-phase transmission unit a2r and the second R-phase receipt unit b2r is located above, and the other is located below.

The second R-phase transmission unit a2r and the second R-phase receipt unit b2r are attached to an outer wall of the 12th holding frame 2a32 or an inner wall of the 12th accommodating region 2a2.

The first S-phase transmission unit a1s transmits a signal to the first S-phase receipt unit b1s.

The first S-phase receipt unit b1s receives the signal from the first S-phase transmission unit a1s.

On the basis of the received signal, the first S-phase receipt unit b1s transmits, to the operation unit 91, information regarding the radio-wave strength of the signal transmitted from the first S-phase transmission unit a1s.

The first S-phase transmission unit a1s and the first S-phase receipt unit b1s are disposed such that when viewed from above, the first S-phase transmission unit a1s and the first S-phase receipt unit b1s have a positional relationship that the first S-phase transmission unit a1s and the first S-phase receipt unit b1s sandwich the 21st holding frame 2b31, and the first S-phase transmission unit a1s and the first S-phase receipt unit b1s have a positional relationship that the first S-phase transmission unit a1s and the first S-phase receipt unit b1s sandwich the 11th S-phase resistor group 11b, the 21st S-phase resistor group 21b, the 110th S-phase resistor group 110b, and the 210th S-phase resistor group 210b.

In addition, when viewed from above, the first S-phase transmission unit a1s and the first S-phase receipt unit b1s have a positional relationship that the first S-phase transmission unit a1s and the first S-phase receipt unit b1s sandwich the 21st holding frame 2b31, and the first S-phase transmission unit a1s and the first S-phase receipt unit b1s are arranged in a direction (y direction) perpendicular to the direction (x direction) in which the resistors R of the 11th S-phase resistor group 11b, the 21st S-phase resistor group 21b, the 110th S-phase resistor group 110b, and the 210th S-phase resistor group 210b extend.

In addition, the first S-phase transmission unit a1s and the first S-phase receipt unit b1s are disposed such that one of the first S-phase transmission unit a1s and the first S-phase receipt unit b1s is located above, and the other is located below.

The first S-phase transmission unit a1s and the first S-phase receipt unit b1s are attached to an outer wall of the 21st holding frame 2b31 or an inner wall of the 21st accommodating region 2b1.

The second S-phase transmission unit a2s transmits a signal to the second S-phase receipt unit b2s.

The second S-phase receipt unit b2s receives the signal from the second S-phase transmission unit a2s.

On the basis of the received signal, the second S-phase receipt unit b2s transmits, to the operation unit 91, information regarding the radio-wave strength of the signal transmitted from the second S-phase transmission unit a2s.

The second S-phase transmission unit a2s and the second S-phase receipt unit b2s are disposed such that when viewed from above, the second S-phase transmission unit a2s and the second S-phase receipt unit b2s have a positional relationship that the second S-phase transmission unit a2s and the second S-phase receipt unit b2s sandwich the 22nd holding frame 2b32, and the second S-phase transmission unit a2s and the second S-phase receipt unit b2s have a positional relationship that the second S-phase transmission unit a2s and the second S-phase receipt unit b2s sandwich the 12th S-phase resistor group 12b, the 22nd S-phase resistor group 22b, the 120th S-phase resistor group 120b, and the 220th S-phase resistor group 220b.

In addition, when viewed from above, the second S-phase transmission unit a2s and the second S-phase receipt unit b2s have a positional relationship that the second S-phase transmission unit a2s and the second S-phase receipt unit b2s sandwich the 22nd holding frame 2b32, and the second S-phase transmission unit a2s and the second S-phase receipt unit b2s are arranged in a direction (y direction) perpendicular to the direction (x direction) in which the resistors R of the 12th S-phase resistor group 12b, the 22nd S-phase resistor group 22b, the 120th S-phase resistor group 120b, and the 220th S-phase resistor group 220b extend.

In addition, the second S-phase transmission unit a2s and the second S-phase receipt unit b2s are disposed such that one of the second S-phase transmission unit a2s and the second S-phase receipt unit b2s is located above, and the other is located below.

The second S-phase transmission unit a2s and the second S-phase receipt unit b2s are attached to an outer wall of the 22nd holding frame 2b32 or an inner wall of the 22nd accommodating region 2b2.

The first T-phase transmission unit a1t transmits a signal to the first T-phase receipt unit b1t.

The first T-phase receipt unit b1t receives the signal from the first T-phase transmission unit a1t.

On the basis of the received signal, the first T-phase receipt unit b1t transmits, to the operation unit 91, information regarding the radio-wave strength of the signal transmitted from the first T-phase transmission unit a1t.

The first T-phase transmission unit a1t and the first T-phase receipt unit b1t are disposed such that when viewed from above, the first T-phase transmission unit a1t and the first T-phase receipt unit b1t have a positional relationship that the first T-phase transmission unit a1t and the first T-phase receipt unit b1t sandwich the 31st holding frame 2c31, and the first T-phase transmission unit a1t and the first T-phase receipt unit b1t have a positional relationship that the first T-phase transmission unit a1t and the first T-phase receipt unit b1t sandwich the 11th T-phase resistor group 11c, the 21st T-phase resistor group 21c, the 110th T-phase resistor group 110c, and the 210th T-phase resistor group 210c.

In addition, when viewed from above, the first T-phase transmission unit a1t and the first T-phase receipt unit b1t have a positional relationship that the first T-phase transmission unit a1t and the first T-phase receipt unit b1t sandwich the 31st holding frame 2c31, and the first T-phase transmission unit a1t and the first T-phase receipt unit b1t are arranged in a direction (y direction) perpendicular to the direction (x direction) in which the resistors R of the 11th T-phase resistor group 11c, the 21st T-phase resistor group 21c, the 110th T-phase resistor group 110c, and the 210th T-phase resistor group 210c extend.

In addition, the first T-phase transmission unit a1t and the first T-phase receipt unit b1t are disposed such that one of the first T-phase transmission unit a1t and the first T-phase receipt unit b1t is located above, and the other is located below.

The first T-phase transmission unit a1t and the first T-phase receipt unit b1t are attached to an outer wall of the 31st holding frame 2c31 or an inner wall of the 31st accommodating region 2c1.

The second T-phase transmission unit a2t transmits a signal to the second T-phase receipt unit b2t.

The second T-phase receipt unit b2t receives the signal from the second T-phase transmission unit a2t.

On the basis of the received signal, the second T-phase receipt unit b2t transmits, to the operation unit 91, information regarding the radio-wave strength of the signal transmitted from the second T-phase transmission unit a2t.

The second T-phase transmission unit a2t and the second T-phase receipt unit b2t are disposed such that when viewed from above, the second T-phase transmission unit a2t and the second T-phase receipt unit b2t have a positional relationship that the second T-phase transmission unit a2t and the second T-phase receipt unit b2t sandwich the 32nd holding frame 2c32, and the second T-phase transmission unit a2t and the second T-phase receipt unit b2t have a positional relationship that the second T-phase transmission unit a2t and the second T-phase receipt unit b2t sandwich the 12th T-phase resistor group 12c, the 22nd T-phase resistor group 22c, the 120th T-phase resistor group 120c, and the 220th T-phase resistor group 220c.

In addition, when viewed from above, the second T-phase transmission unit a2t and the second T-phase receipt unit b2t have a positional relationship that the second T-phase transmission unit a2t and the second T-phase receipt unit b2t sandwich the 32nd holding frame 2c32, and the second T-phase transmission unit a2t and the second T-phase receipt unit b2t are arranged in a direction (y direction) perpendicular to the direction (x direction) in which the resistors R of the 12th T-phase resistor group 12c, the 22nd T-phase resistor group 22c, the 120th T-phase resistor group 120c, and the 220th T-phase resistor group 220c extend.

In addition, the second T-phase transmission unit a2t and the second T-phase receipt unit b2t are disposed such that one of the second T-phase transmission unit a2t and the second T-phase receipt unit b2t is located above, and the other is located below.

The second T-phase transmission unit a2t and the second T-phase receipt unit b2t are attached to an outer wall of the 32nd holding frame 2c32 or an inner wall of the 32nd accommodating region 2c2.

Conceivable communication means of communication between the first R-phase transmission unit a1r and the first R-phase receipt unit b1r, communication between the second R-phase transmission unit a2r and the second R-phase receipt unit b2r, communication between the first S-phase transmission unit a1s and the first S-phase receipt unit b1s, communication between the second S-phase transmission unit a2s and the second S-phase receipt unit b2s, communication between the first T-phase transmission unit a1t and the first T-phase receipt unit b1t, and communication between the second T-phase transmission unit a2t and the second T-phase receipt unit b2t are a telephone line and an RF tag communication system, as well as a communication means that transmits its own identification information to the outside while a wireless communication means in question is in the on state, such as IEEE 802.15.1 (Bluetooth (registered trademark), 2.4 GHz), and IEEE 802.11 (wireless LAN, 2.4 GHz or 5 GHz).

In addition, this communication is performed with wireless communication of a frequency (first frequency band f1) that does not pass through walls of the first accommodating region 2a and the like.

Communication between the first R-phase receipt unit b1r and the operation unit 91, communication between the second R-phase receipt unit b2r and the operation unit 91, communication between the first S-phase receipt unit b1s and the operation unit 91, communication between the second S-phase receipt unit b2s and the operation unit 91, communication between the first T-phase receipt unit b1t and the operation unit 91, and communication between the second T-phase receipt unit b2t and the operation unit 91 are performed with wired communication or wireless communication of a frequency (second frequency band f2) that passes through walls of the first accommodating region 2a.

Transmission of the first R-phase transmission unit a1r, the second R-phase transmission unit a2r, the first S-phase transmission unit a1s, the second S-phase transmission unit a2s, the first T-phase transmission unit a1t, and the second T-phase transmission unit a2t is performed at a time of inspection of the load-testing apparatus 1, that is, when the inspection mode is selected in mode-switching of the operation unit 91.

Transmission of the first R-phase transmission unit a1r, the second R-phase transmission unit a2r, the first S-phase transmission unit a1s, the second S-phase transmission unit a2s, the first T-phase transmission unit a1t, and the second T-phase transmission unit a2t may be simultaneously performed, but may be sequentially performed with time differences provided, so that the receipt unit does not accidentally receive a signal from another transmission unit.

For example, transmission of the first R-phase transmission unit a1r is performed for a first time period t1 (for example, t1=0.5 seconds). After the transmission, after a second time period t2 (for example, t2=1 second) elapses, transmission of the second R-phase transmission unit a2r is performed for the first time period t1. After the second time period t2 elapses, transmission of the first S-phase transmission unit a1s is performed for the first time period t1.

(Operation Unit 91)

The operation unit 91 is used for on/off-operation of the load-testing apparatus 1, selection of the type of a test target power source (mode-switching), and selection of the load amount.

The on/off state of the switches, such as the 13th relay unit 13, are controlled according to the operation state of the operation unit 91.

(On/Off-Operation of Load-Testing Apparatus 1)

When operation is performed to turn the load-testing apparatus 1 into the on state, the first main relay unit 5 is turned into the on state, so that a transition to a state where power can be supplied from a test target power source connected through the terminal unit 93 is made. In addition, the cooling unit 80 is driven.

(Mode-Switching)

When operation related to mode-switching is performed, on/off-control of the switches (13th relay unit 13) and the like is performed according to the operation state of the mode-switching.

For example, in a case where a load test mode corresponding to a high-voltage test target power source is selected, on/off-control of the switches is performed such that two resistor groups adjacent in the y direction, such as the 11th R-phase resistor group 11a and the 12th R-phase resistor group 12a, are connected in series.

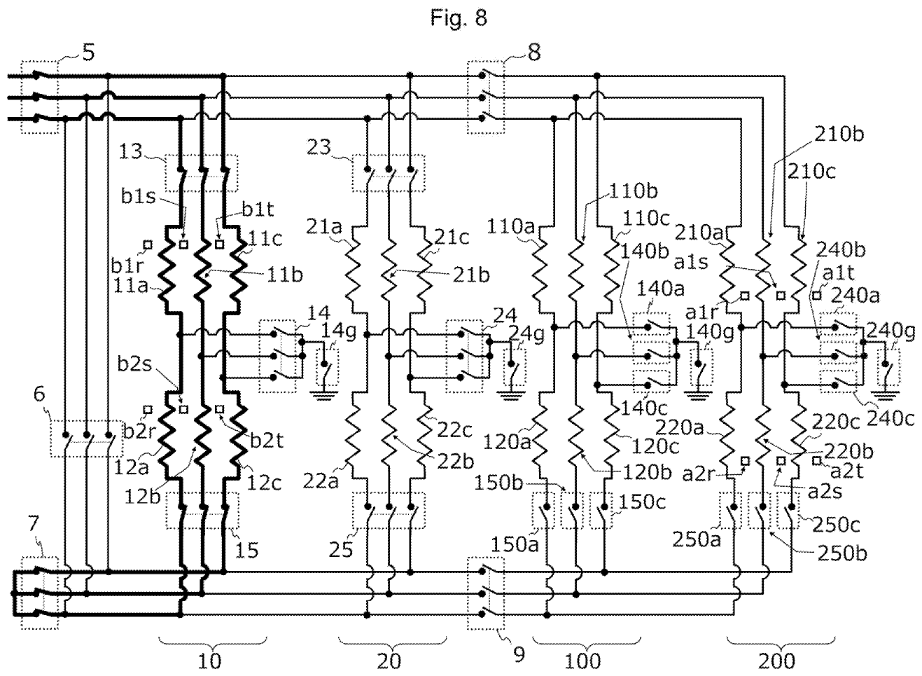

More specifically, the second main relay unit 6, the 14th relay unit 14, the 14th grounding relay 14g, the 24th relay unit 24, the 24th grounding relay 24g, the 140th R-phase relay 140a, the 140th S-phase relay 140b, the 140th T-phase relay 140c, the 140th grounding relay 140g, the 240th R-phase relay 240a, the 240th S-phase relay 240b, the 240th T-phase relay 240c, and the 240th grounding relay 240g are turned into the off state, and the third main relay unit 7 is turned into the on state (see FIG. 8).

Alternatively, in a case where a load test mode corresponding to a low-voltage test target power source is selected, on/off-control of the switches is performed such that two resistor groups adjacent in the y direction, such as the 11th R-phase resistor group 11a and the 12th R-phase resistor group 12a, are connected in parallel.

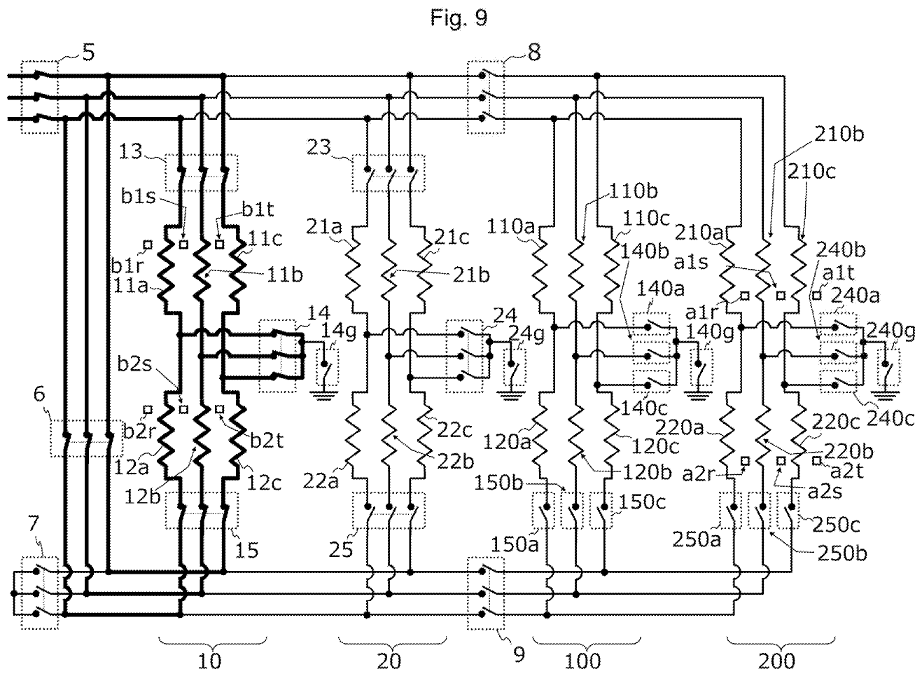

More specifically, the second main relay unit 6, the 14th relay unit 14, the 24th relay unit 24, the 140th R-phase relay 140a, the 140th S-phase relay 140b, the 140th T-phase relay 140c, the 240th R-phase relay 240a, the 240th S-phase relay 240b, and the 240th T-phase relay 240c are turned into the on state, and the third main relay unit 7, the 14th grounding relay 14g, the 24th grounding relay 24g, the 140th grounding relay 140g, and the 240th grounding relay 240g are turned into the off state (see FIG. 9).

However, among the 14th relay unit 14, the 24th relay unit 24, the 140th R-phase relay 140a, the 140th S-phase relay 140b, the 140th T-phase relay 140c, the 240th R-phase relay 240a, the 240th S-phase relay 240b, and the 240th T-phase relay 240c, the relay units and the relays included in the resistance units that do not perform the power supply may be turned into the off state.

In order to prevent accidental power supply to the resistor groups and the like at a time of switching these relays, the 14th relay unit 14 and the like are switched on and off in a state where the first fine-adjustment relay unit 8, the second fine-adjustment relay unit 9, the 13th relay unit 13, the 15th relay unit 15, the 23rd relay unit 23, and the 25th relay unit 25 are in the off state.

That is, in a state where power supply from the test target power source to the first resistance unit 10 through the terminal unit 93 is not performed, switching of the state of connection between the 11th R-phase resistor group 11a and the 12th R-phase resistor group 12a, switching of the state of connection between the 11th S-phase resistor group 11b and the 12th S-phase resistor group 12b, and switching of the state of connection between the 11th T-phase resistor group 11c and the 12th T-phase resistor group 12c are performed.

In addition, in a state where power supply from the test target power source to the second resistance unit 20 through the terminal unit 93 is not performed, switching of the state of connection between the 21st R-phase resistor group 21a and the 22nd R-phase resistor group 22a, switching of the state of connection between the 21st S-phase resistor group 21b and the 22nd S-phase resistor group 22b, and switching of the state of connection between the 21st T-phase resistor group 21c and the 22nd T-phase resistor group 22c are performed.

In addition, in a state where power supply from the test target power source to the 10th resistance unit 100 through the terminal unit 93 is not performed, switching of the state of connection between the 110th R-phase resistor group 110a and the 120th R-phase resistor group 120a, switching of the state of connection between the 110th S-phase resistor group 110b and the 120th S-phase resistor group 120b, and switching of the state of connection between the 110th T-phase resistor group 110c and the 120th T-phase resistor group 120c are performed.

In addition, in a state where power supply from the test target power source to the 20th resistance unit 200 through the terminal unit 93 is not performed, switching of the state of connection between the 210th R-phase resistor group 210a and the 220th R-phase resistor group 220a, switching of the state of connection between the 210th S-phase resistor group 210b and the 220th S-phase resistor group 220b, and switching of the state of connection between the 210th T-phase resistor group 210c and the 220th T-phase resistor group 220c are performed.

(Selection of Load Amount)

When operation related to selection of the load amount is performed, on/off-control of the relays (such as the 13th relay unit 13) is performed according to the selected load amount.

For example, in a case where fine adjustment of the load amount is not performed and a first load amount is selected from two levels, the 13th relay unit 13 and the 15th relay unit 15 are turned into the on state, and the 23rd relay unit 23 and the 25th relay unit 25 are turned into the off state (see FIGS. 8 and 9). In addition, the first fine-adjustment relay unit 8 and the second fine-adjustment relay unit 9 are turned into the off state.

In this case, power supply from a test target power source to the first resistance unit 10 is performed, and power supply from the test target power source to the second resistance unit 20, the 10th resistance unit 100, and the 20th resistance unit 200 is not performed.

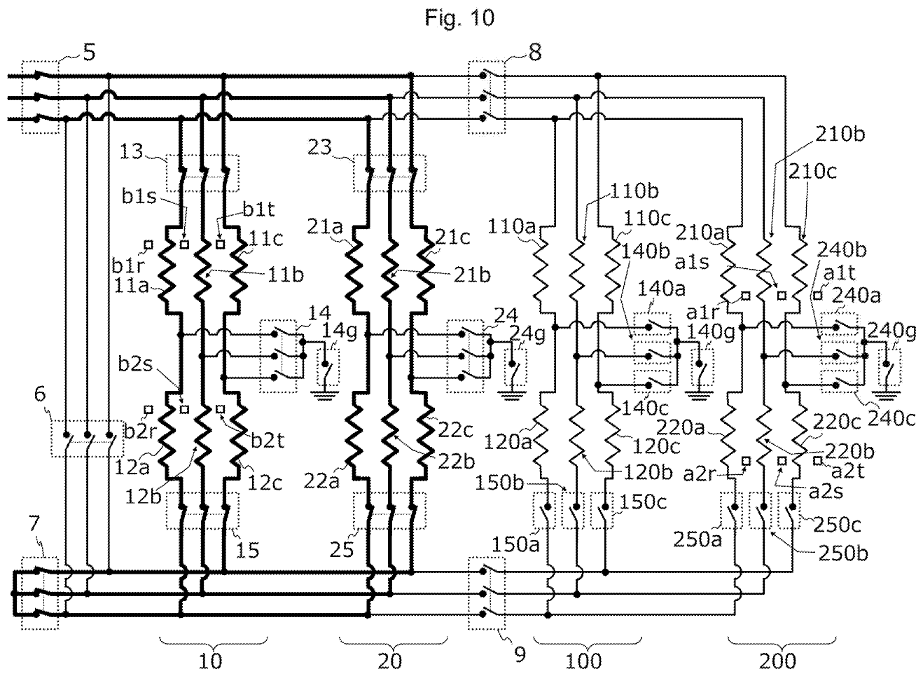

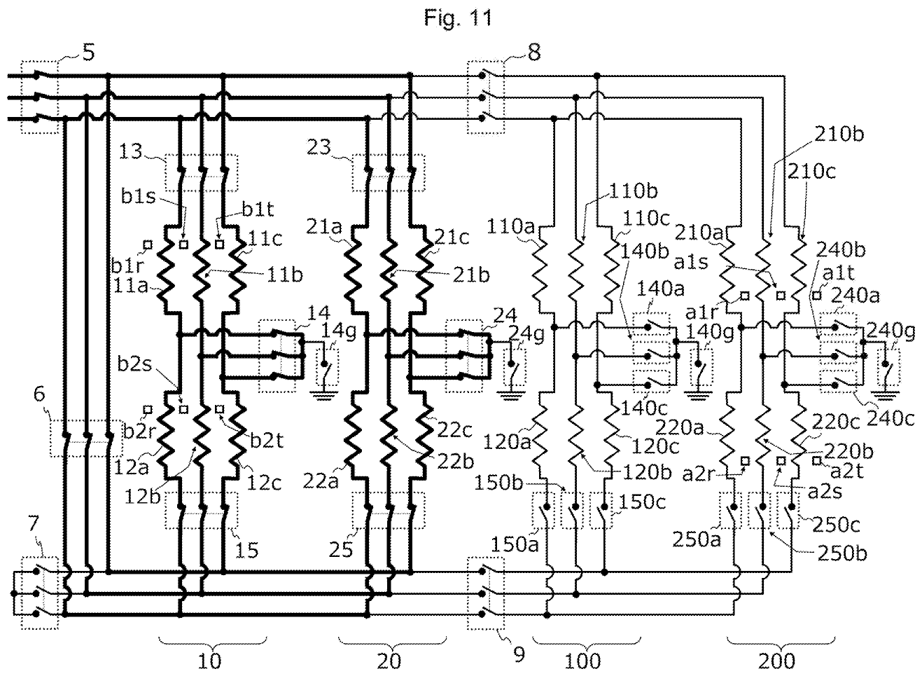

Alternatively, in a case where fine adjustment of the load amount is not performed and a second load amount is selected from the two levels, the 13th relay unit 13, the 15th relay unit 15, the 23rd relay unit 23, and the 25th relay unit 25 are turned into the on state (see FIGS. 10 and 11). In addition, the first fine-adjustment relay unit 8 and the second fine-adjustment relay unit 9 are turned into the off state.

In this case, power supply from a test target power source to the first resistance unit 10 and the second resistance unit 20 is performed, and power supply from the test target power source to the 10th resistance unit 100 and the 20th resistance unit 200 is not performed.

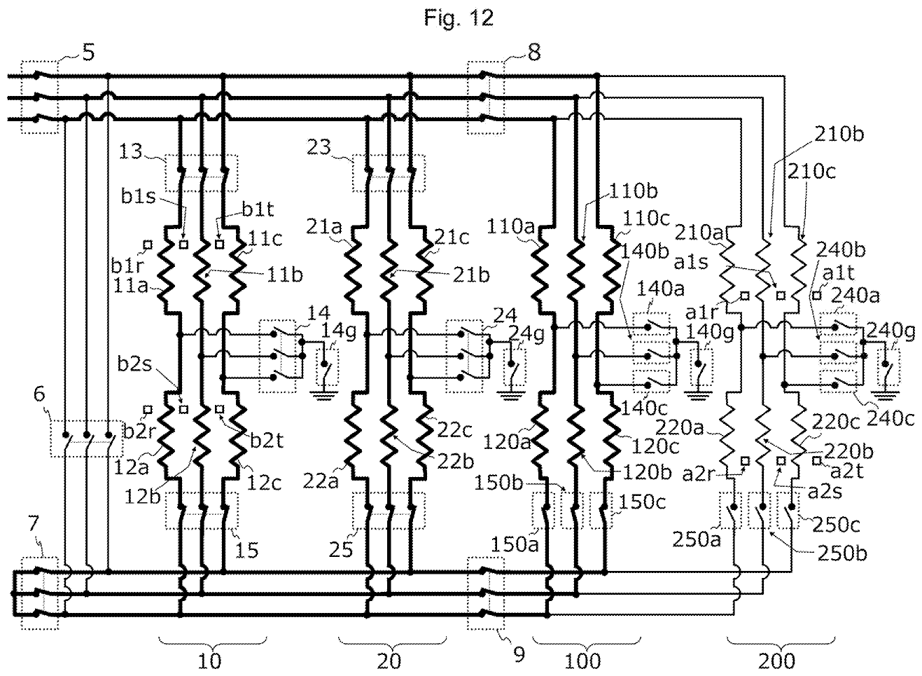

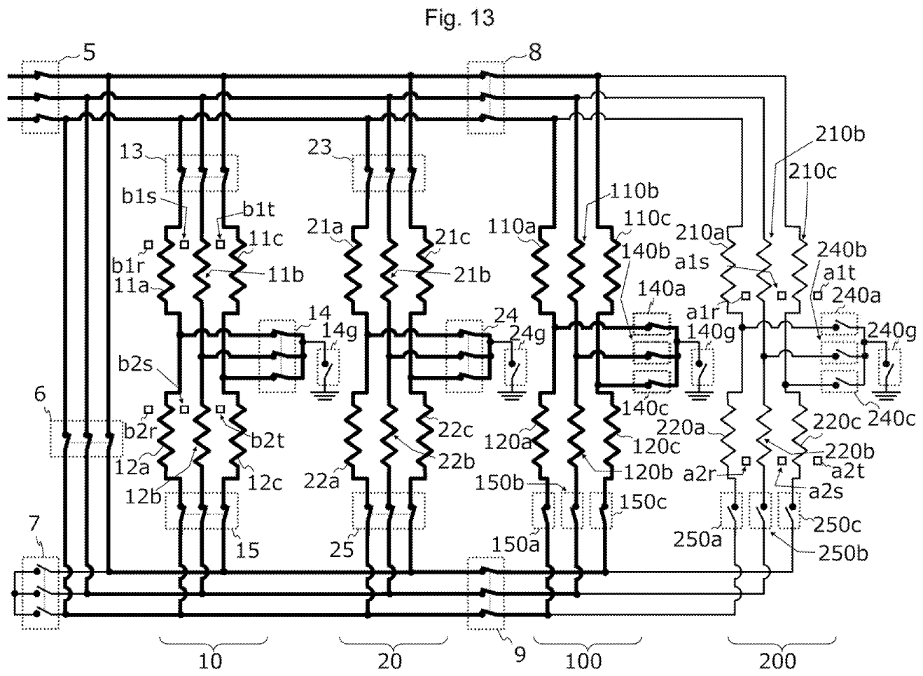

Alternatively, in a case where fine adjustment of the load amount is performed and the second load amount is selected from the two levels, the 13th relay unit 13, the 15th relay unit 15, the 23rd relay unit 23, and the 25th relay unit 25 are turned into the on state (see FIGS. 12 and 13).

In addition, the first fine-adjustment relay unit 8, the second fine-adjustment relay unit 9, the 150th R-phase relay 150a, the 150th S-phase relay 150b, and the 150th T-phase relay 150c are turned into the on state, and the 250th R-phase relay 250a, the 250th S-phase relay 250b, and the 250th T-phase relay 250c are turned into the off state.

In this case, power supply from a test target power source to the first resistance unit 10, the second resistance unit 20, and the 10th resistance unit 100 is performed, and power supply from the test target power source to the 20th resistance unit 200 is not performed.

However, according to the degree of the fine adjustment, the 250th R-phase relay 250a, the 250th S-phase relay 250b, and the 250th T-phase relay 250c may be turned into the on state. In this case, power supply from a test target power source to the first resistance unit 10, the second resistance unit 20, the 10th resistance unit 100, and the 20th resistance unit 200 is performed.

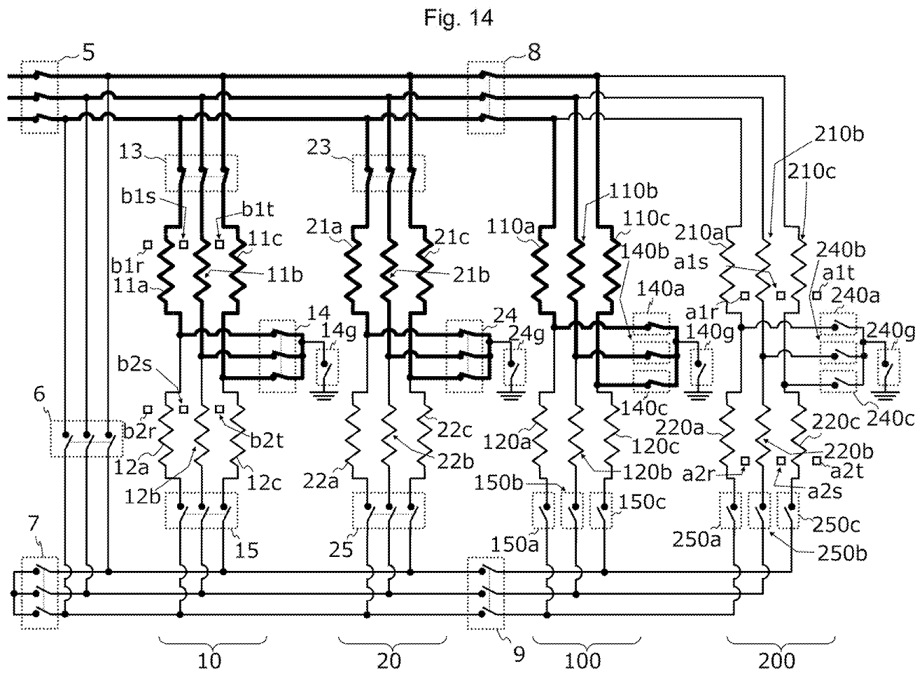

Alternatively, in a case where a small load amount is set, only power supply to one or some of the resistor groups of the resistance units may be performed (see FIG. 14).

FIG. 14 illustrates an example in which power supply to the resistor groups included in the 11th accommodating region 2a1, the 21st accommodating region 2b1, and the 31st accommodating region 2c1 is performed, and power supply to the resistor groups included in the 12th accommodating region 2a2, the 22nd accommodating region 2b2, and the 32nd accommodating region 2c2 is not performed.

More specifically, the second main relay unit 6, the third main relay unit 7, the second fine-adjustment relay unit 9, the 15th relay unit 15, the 25th relay unit 25, the 150th R-phase relay 150a, the 150th S-phase relay 150b, the 150th T-phase relay 150c, the 250th R-phase relay 250a, the 250th S-phase relay 250b, and the 250th T-phase relay 250c are turned into the off state.

In addition, controlled according to the set load amount are the on/off states of the first fine-adjustment relay unit 8, the 13th relay unit 13, the 14th relay unit 14, the 23rd relay unit 23, the 24th relay unit 24, the 140th R-phase relay 140a, the 140th S-phase relay 140b, the 140th T-phase relay 140c, the 240th R-phase relay 240a, the 240th S-phase relay 240b, and the 240th T-phase relay 240c.

FIG. 14 illustrates a state where the first fine-adjustment relay unit 8, the 13th relay unit 13, the 14th relay unit 14, the 23rd relay unit 23, the 24th relay unit 24, the 140th R-phase relay 140a, the 140th S-phase relay 140b, and the 140th T-phase relay 140c are turned into the on state, and the 240th R-phase relay 240a, the 240th S-phase relay 240b, and the 240th T-phase relay 240c are turned into the off state.

(Inspection Mode of Load-Testing Apparatus 1)

In addition, in a case where the inspection mode of the load-testing apparatus 1 is selected, on/off-control of the switches is performed so that the resistor groups are grounded. In addition, the lids (first R-phase air inlet lid 2a13, second R-phase air inlet lid 2a14, first R-phase air outlet lid 2a23, second R-phase air outlet lid 2a24, first S-phase air inlet lid 2b13, second S-phase air inlet lid 2b14, first S-phase air outlet lid 2b23, second S-phase air outlet lid 2b24, first T-phase air inlet lid 2c13, second T-phase air inlet lid 2c14, first T-phase air outlet lid 2c23, second T-phase air outlet lid 2c24) are closed. In a case where said lids are manually opened and closed, the operation unit 91 or the like outputs a warning display or a warning sound to notify the user to close said lids.

The inspection of the load-testing apparatus 1 is performed, for example, immediately before a load test is performed.

More specifically, the 14th relay unit 14, the 14 th grounding relay 14g, the 24th relay unit 24, the 24th grounding relay 24g, the 140th R-phase relay 140a, the 140th S-phase relay 140b, the 140th T-phase relay 140c, the 140th grounding relay 140g, the 240th R-phase relay 240a, the 240th S-phase relay 240b, the 240th T-phase relay 240c, and the 240th grounding relay 240g are turned into the on state, and the first main relay unit 5 is turned into the off state (see FIGS. 15 and 16).

The other relays (second main relay unit 6, third main relay unit 7, first fine-adjustment relay unit 8, second fine-adjustment relay unit 9, 13th relay unit 13, 15th relay unit 15, 23rd relay unit 23, 25th relay unit 25, 150th R-phase relay 150a, 150th S-phase relay 150b, 150th T-phase relay 150c, 250th R-phase relay 250a, 250th S-phase relay 250b, and 250th T-phase relay 250c) are turned into the off state, but may be turned into the on state.

In order to prevent accidental power supply to the resistor groups and the like at a time of switching these relays, the 14th grounding relay 14g and the like are switched on and off in a state where the first main relay unit 5 is in the off state.

That is, on/off switching of grounding of the resistor groups, such as the 11th R-phase resistor group 11a, is performed in a state where power supply from a test target power source to the first resistance unit 10 through the terminal unit 93 is not performed.

In addition, the operation unit 91 functions as a totaling unit. On the basis of information from the first R-phase receipt unit b1r and the like regarding the radio-wave strength, the operation unit 91 determines whether or not a failure has occurred in the resistors and the like.

For example, in a case where there is wire breaking of any of the resistors R or the cable of the resistor group (such as the 11th R-phase resistor group 11a) held by the 11th holding frame 2a31, there is a high possibility, as compared with a case where there is no wire breaking, that the radio-wave strength varies.

In particular, in a case where the resistor group is grounded, the length of a region of the resistor R or the cable electrically connected to the grounded surface varies for a state where there is no wire breaking (see FIG. 15) and a state where there is wire breaking (see FIG. 16). Therefore, a difference in the radio-wave strength is likely to appear.

The operation unit 91 records at least one of information regarding the radio-wave strength at a normal time or information regarding the radio-wave strength at an abnormal time (at a time of wire breaking) to determine, on the basis of information from the first R-phase receipt unit b1r or the like regarding the radio-wave strength, whether or not a failure has occurred in any of the resistors R or the cable of the corresponding resistor group.

In a case where it is determined that a failure has occurred in any of the resistors R or the cable of said resistor group, the operation unit 91 outputs a warning display or a warning sound to notify the user.

For example, since in the state of FIG. 16, a failure has occurred in a resistor R of the 11th R-phase resistor group 11a, there is a large difference between the information from the first R-phase receipt unit b1r regarding the radio-wave strength, and that in a normal time. In addition, there is a small difference between the information from the other receipt units (second R-phase receipt unit b2r, first S-phase receipt unit b1s, second S-phase receipt unit b2s, first T-phase receipt unit b1t, and second T-phase receipt unit b2t) regarding the radio-wave strength, and that in a normal time.

Note that in addition to the information regarding the radio-wave strength or instead of the information regarding the radio-wave strength, the operation unit 91 may use a difference between a waveform of a signal transmitted from the transmission unit and a preset reference signal waveform to determine whether or not a failure has occurred in the resistors R and the like.

Alternatively, the determination as to whether or not a failure has occurred in the resistor R and the like may be performed, in addition to the operation unit 91 or instead of the operation unit 91, by another device inside the load-testing apparatus 1 (for example, a control device), or by another device outside the load-testing apparatus 1 (for example, a mobile terminal).

In this case, said another device functions as a totaling unit, and information from the first R-phase receipt unit b1r and the like regarding the radio-wave strength is transmitted to said another device.

The terminal unit 93 is a terminal for connecting a test target power source.

The test target power source and the first main relay unit 5 are electrically connected through the terminal unit 93.

(Power Source for Driving Switches, Cooling Unit, and the Like)

Electric equipment constituting the load-testing apparatus 1, such as the 13th relay unit 13 and the first R-phase-cooling unit 81a, except the resistor groups, such as the 11th R-phase resistor group 11a, may be driven on the basis of power supply from a power source (for example, mains electricity) different from a test target power source, or may be driven on the basis of power supply from a test target power source.

(Application Example of Short-Circuit Switch)

In the first embodiment, an example has been described in which the short-circuit switches for neutral-point connection at a time when the resistor groups adjacent in the y direction are connected in parallel (14th relay unit 14, 24th relay unit 24, 140th R-phase relay 140a, 140th S-phase relay 140b, 140th T-phase relay 140c, 240th R-phase relay 240a, 240th S-phase relay 240b, 240th T-phase relay 240c) are separately provided for each stage.

However, one short-circuit switch (for example, the 14th relay unit 14) may be shared for neutral-point connection at a time when the resistor groups adjacent in the y direction in another stage are connected in parallel.

In addition, an example has been described in which the short-circuit switch (third main relay unit 7) for neutral-point connection at a time when the resistor groups adjacent in the y direction are connected in series is shared for neutral-point connection at a time when the resistor groups adjacent in the y direction in another stage are connected in series.

However, short-circuit switches for neutral-point connection at a time when the resistor groups adjacent in the y direction are connected in series may be separately provided for each stage.

(Application Example of Disposition of Transmission Unit and Receipt Unit)

In addition, in the first embodiment, an example has been described in which when viewed from above, the first R-phase transmission unit a1r and the first R-phase receipt unit b1r have a positional relationship that the first R-phase transmission unit a1r and the first R-phase receipt unit b1r sandwich the 11th holding frame 2a31, and the first R-phase transmission unit a1r and the first R-phase receipt unit b1r are arranged in a direction (y direction) perpendicular to the direction (x direction) in which the resistors R of the 11th R-phase resistor group 11a, the 21st R-phase resistor group 21a, the 110th R-phase resistor group 110a, and the 210th R-phase resistor group 210a extend.

However, when viewed from above, the first R-phase transmission unit a1r and the first R-phase receipt unit b1r have a positional relationship that the first R-phase transmission unit a1r and the first R-phase receipt unit b1r sandwich the 11th holding frame 2a31, and the first R-phase transmission unit a1r and the first R-phase receipt unit b1r may be arranged in a direction (x direction) parallel to the direction (x direction) in which the resistors R of the 11th R-phase resistor group 11a, the 21st R-phase resistor group 21a, the 110th R-phase resistor group 110a, and the 210th R-phase resistor group 210a extend.

Alternatively, the first R-phase transmission unit a1r and the first R-phase receipt unit b1r may be disposed such that the first R-phase transmission unit a1r and the first R-phase receipt unit b1r are shifted in the x direction. For example, when viewed from above, the first R-phase transmission unit a1r is disposed closer to the x-direction front side than the first R-phase receipt unit b1r is.

(Application Example of Number of Sets of Transmission Unit and Receipt Unit)

In the first embodiment, an example in which a set of the transmission unit and the receipt unit is provided for each holding frame has been described.

However, only one set of a transmission unit and a receipt unit may be provided for two adjacent holding frames.

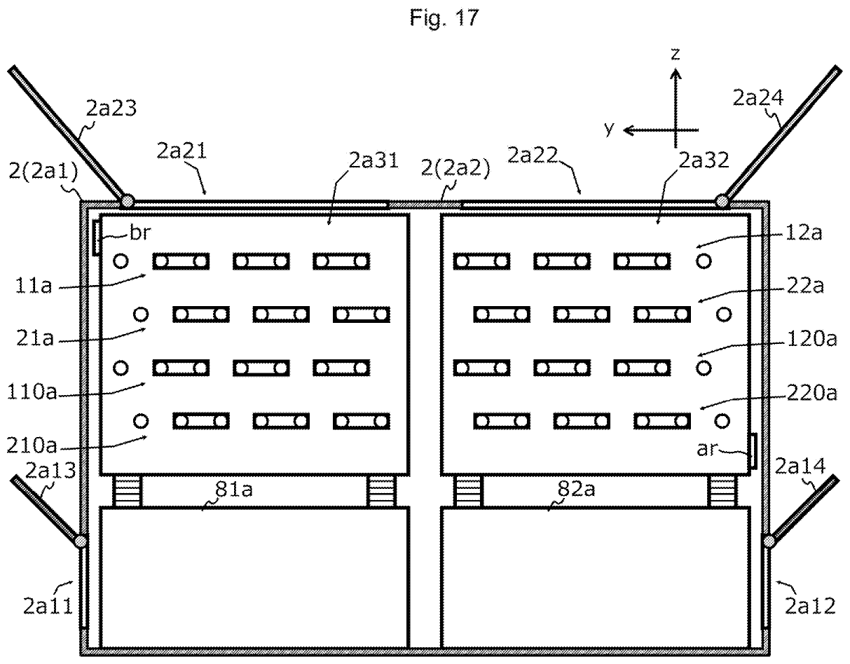

For example, conceivable is an embodiment in which an R-phase transmission unit ar is provided for the 12th holding frame 2a32 and an R-phase receipt unit br is provided for the 11th holding frame 2a31 (see FIG. 17).

The R-phase transmission unit ar transmits a signal to the R-phase receipt unit br.

The R-phase receipt unit br receives the signal from the R-phase transmission unit ar.

On the basis of the received signal, the R-phase receipt unit br transmits, to the operation unit 91, information regarding the radio-wave strength of the signal transmitted from the R-phase transmission unit ar.

The R-phase transmission unit ar and the R-phase receipt unit br are disposed such that when viewed from above, the R-phase transmission unit ar and the R-phase receipt unit br have a positional relationship that the R-phase transmission unit ar and the R-phase receipt unit br sandwich the 11th holding frame 2a31 and the 12th holding frame 2a32, and the R-phase transmission unit ar and the R-phase receipt unit br have a positional relationship that the R-phase transmission unit ar and the R-phase receipt unit br sandwich the 11th R-phase resistor group 11a, the 12th R-phase resistor group 12a, the 21st R-phase resistor group 21a, the 22nd R-phase resistor group 22a, the 110th R-phase resistor group 110a, the 120th R-phase resistor group 120a, the 210th R-phase resistor group 210a, and the 220th R-phase resistor group 220a

In addition, the R-phase transmission unit ar and the R-phase receipt unit br are disposed such that one of the R-phase transmission unit ar and the R-phase receipt unit br is located above, and the other is located below.

The R-phase transmission unit ar is attached to an outer wall of the 12th holding frame 2a32 or an inner wall of the 12th accommodating region 2a2.

The R-phase receipt unit br is attached to an outer wall of the 11th holding frame 2a31 or an inner wall of the 11th accommodating region 2a1.

An outer wall of the first accommodating region 2a is not provided between the 11th holding frame 2a31 and the 12th holding frame 2a32.

In addition, on the basis of the information from the R-phase receipt unit br regarding the radio-wave strength, the operation unit 91 determines whether or not a failure has occurred in the resistors R of the resistor groups held by the 11th holding frame 2a31 and the resistor groups held by the 12th holding frame 2a32.

Alternatively, only one set of a transmission unit and a receipt unit may be provided for all the holding frames.

Alternatively, a plurality of sets of a transmission unit and a receipt unit may be provided for one holding frame to finely identify a region including a resistor R or the like in which a failure has occurred.

For example, conceivable is an embodiment in which a set of a transmission unit and a receipt unit corresponding to the 11th R-phase resistor group 11a, a set of a transmission unit and a receipt unit corresponding to the 21st R-phase resistor group 21a, a set of a transmission unit and a receipt unit corresponding to the 110th R-phase resistor group 110a, and a set of a transmission unit and a receipt unit corresponding to the 210th R-phase resistor group 210a are provided.

In this case, since a set of a transmission unit and a receipt unit is provided for each stage, the transmission unit and the receipt unit are attached at substantially the same height.

(Application Example of Number of Levels of Load Amount)

In the first embodiment, an example in which the four resistance units (first resistance unit 10, second resistance unit 20, 10th resistance unit 100, and 20th resistance unit 200) are used to allow the two-level adjustment of the load amount and the two-level fine adjustment of the load amount has been described.

However, the number of levels of adjustment of the load amount is not limited to four.

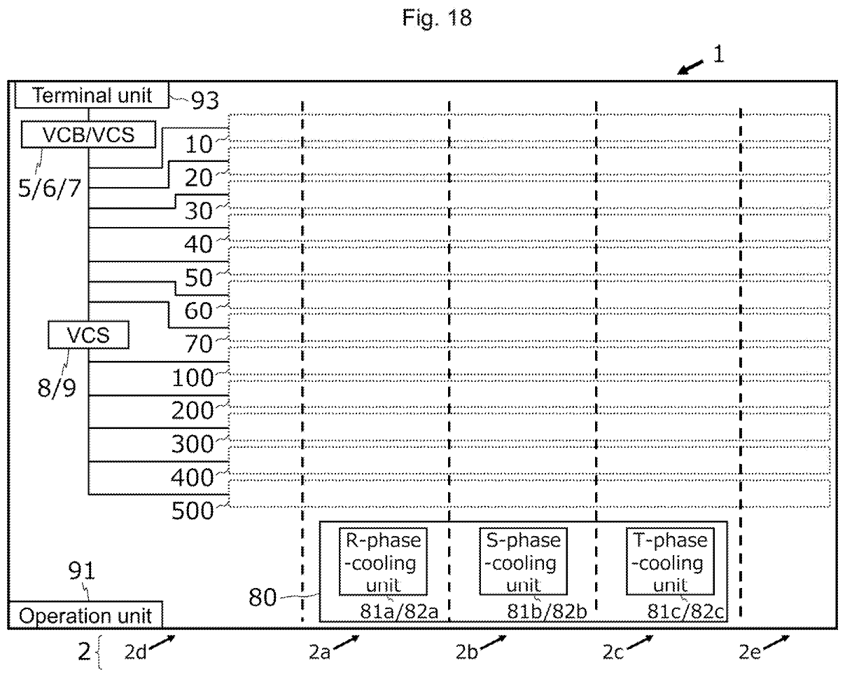

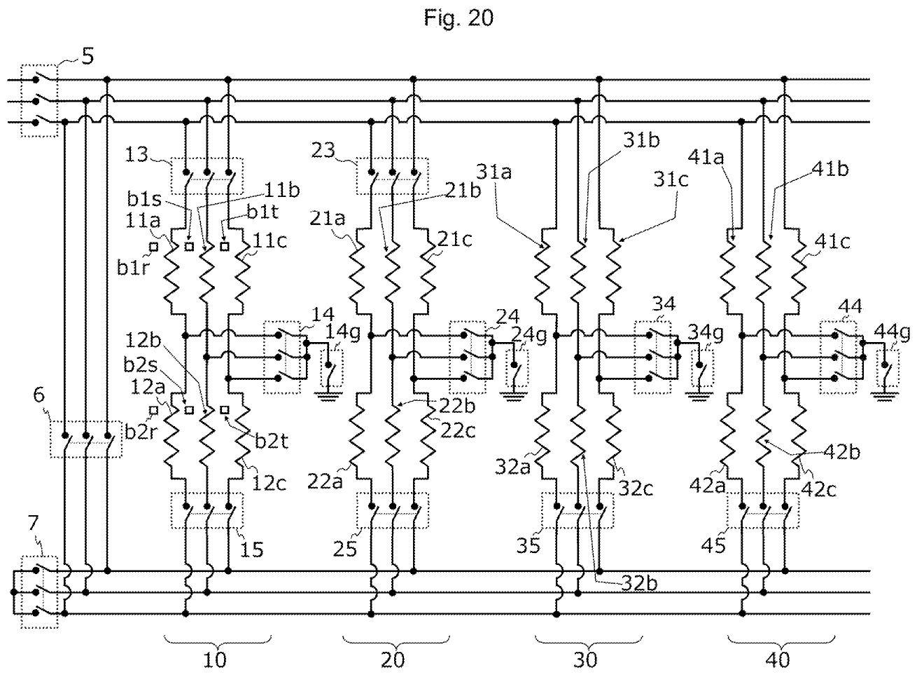

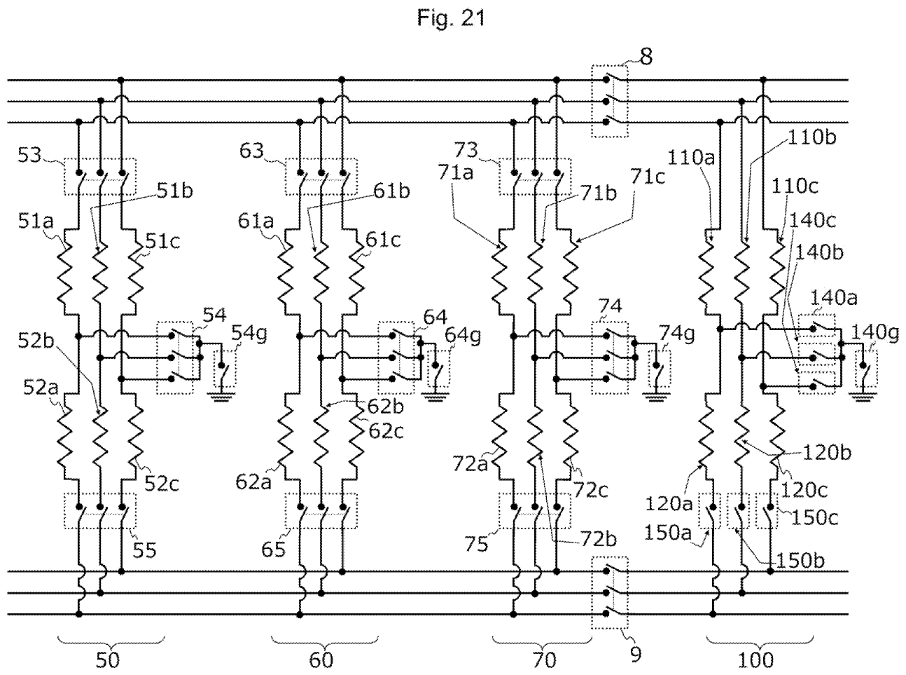

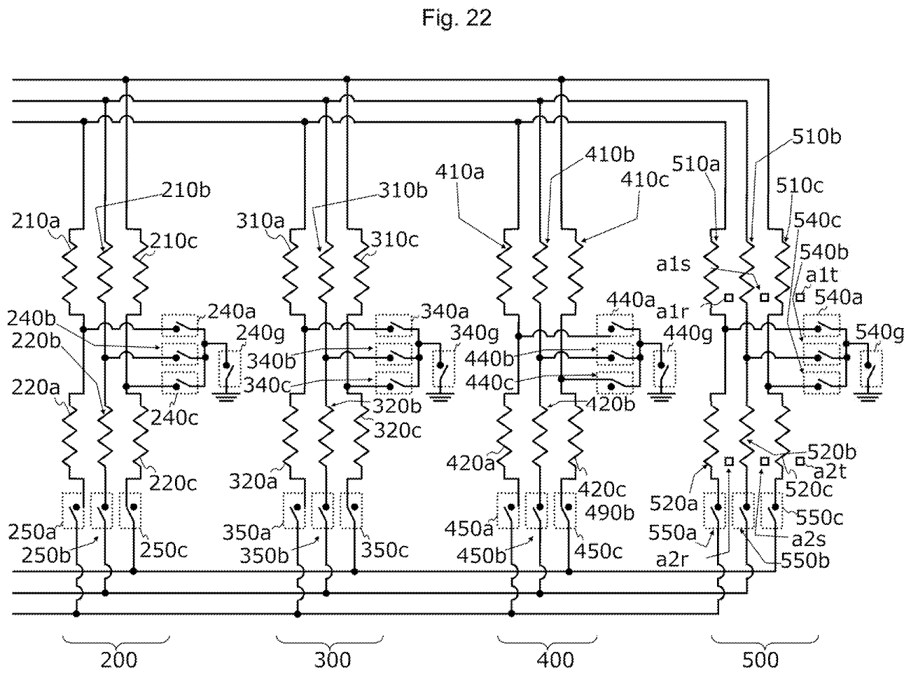

For example, conceivable is an embodiment in which seven-level adjustment of the load amount, and five-level fine adjustment of the load amount are possible (second embodiment, see FIGS. 18 to 22).

A dry-type load-testing apparatus 1 according to the second embodiment includes a housing 2, a first main relay unit 5, a second main relay unit 6, a third main relay unit 7, a first fine-adjustment relay unit 8, a second fine-adjustment relay unit 9, a first resistance unit 10 to a seventh resistance unit 70, a 10th resistance unit 100 to a 50th resistance unit 500, a cooling unit 80, an operation unit 91, and a terminal unit 93.

The configurations of the housing 2, the first main relay unit 5, the second main relay unit 6, the third main relay unit 7, the first fine-adjustment relay unit 8, the second fine-adjustment relay unit 9, the first resistance unit 10, the second resistance unit 20, the 10th resistance unit 100, the 20th resistance unit 200, the cooling unit 80, the operation unit 91, and the terminal unit 93 of the second embodiment are similar to the configurations of the first embodiment.

(Third Resistance Unit 30)

The third resistance unit 30 includes a 31st R-phase resistor group 31a, a 31st S-phase resistor group 31b, a 31st T-phase resistor group 31c, a 32nd R-phase resistor group 32a, a 32nd S-phase resistor group 32b, a 32nd T-phase resistor group 32c, and a third switch group (a 33rd relay unit 33, a 34th relay unit 34, and a 35th relay unit 35).

The configuration of the third resistance unit 30 is similar to the configuration of the first resistance unit 10.

(Fourth Resistance Unit 40)

The fourth resistance unit 40 includes a 41st R-phase resistor group 41a, a 41st S-phase resistor group 41b, a 41st T-phase resistor group 41c, a 42nd R-phase resistor group 42a, a 42nd S-phase resistor group 42b, a 42nd T-phase resistor group 42c, and a fourth switch group (a 43rd relay unit 43, a 44th relay unit 44, and a 45th relay unit 45).

The configuration of the fourth resistance unit 40 is similar to the configuration of the first resistance unit 10.

(Fifth Resistance Unit 50)

The fifth resistance unit 50 includes a 51st R-phase resistor group 51a, a 51st S-phase resistor group 51b, a 51st T-phase resistor group 51c, a 52nd R-phase resistor group 52a, a 52nd S-phase resistor group 52b, a 52nd T-phase resistor group 52c, and a fifth switch group (a 53rd relay unit 53, a 54th relay unit 54, and a 55th relay unit 55).

The configuration of the fifth resistance unit 50 is similar to the configuration of the first resistance unit 10.

(Sixth Resistance Unit 60)

The sixth resistance unit 60 includes a 61st R-phase resistor group 61a, a 61st S-phase resistor group 61b, a 61st T-phase resistor group 61c, a 62nd R-phase resistor group 62a, a 62nd S-phase resistor group 62b, a 62nd T-phase resistor group 62c, and a sixth switch group (a 63rd relay unit 63, a 64th relay unit 64, and a 65th relay unit 65).

The configuration of the sixth resistance unit 60 is similar to the configuration of the first resistance unit 10.

(Seventh Resistance Unit 70)

The seventh resistance unit 70 includes a 71st R-phase resistor group 71a, a 71st S-phase resistor group 71b, a 71st T-phase resistor group 71c, a 72nd R-phase resistor group 72a, a 72nd S-phase resistor group 72b, a 72nd T-phase resistor group 72c, and a seventh switch group (a 73rd relay unit 73, a 74th relay unit 74, and a 75th relay unit 75).

The configuration of the seventh resistance unit 70 is similar to the configuration of the first resistance unit 10.

(30th Resistance Unit 300)

The 30th resistance unit 300 includes a 310th R-phase resistor group 310a, a 310th S-phase resistor group 310b, a 310th T-phase resistor group 310c, a 320th R-phase resistor group 320a, a 320th S-phase resistor group 320b, a 320th T-phase resistor group 320c, and a 30th switch group (a 340th R-phase relay 340a, a 340th S-phase relay 340b, a 340th T-phase relay 340c, a 350th R-phase relay 350a, a 350th S-phase relay 350b, and a 350th T-phase relay 350c).

The configuration of the 30th resistance unit 300 is similar to the configuration of the 10th resistance unit 100.

(40th Resistance Unit 400)

The 40th resistance unit 400 includes a 410th R-phase resistor group 410a, a 410th S-phase resistor group 410b, a 410th T-phase resistor group 410c, a 420th R-phase resistor group 420a, a 420th S-phase resistor group 420b, a 420th T-phase resistor group 420c, and a 40th switch group (a 440th R-phase relay 440a, a 440th S-phase relay 440b, a 440th T-phase relay 440c, a 450th R-phase relay 450a, a 450th S-phase relay 450b, and a 450th T-phase relay 450c).

The configuration of the 40th resistance unit 400 is similar to the configuration of the 10th resistance unit 100.

(50th Resistance Unit 500)

The 50th resistance unit 500 includes a 510th R-phase resistor group 510a, a 510th S-phase resistor group 510b, a 510th T-phase resistor group 510c, a 520th R-phase resistor group 520a, a 520th S-phase resistor group 520b, a 520th T-phase resistor group 520c, and a 50th switch group (a 540th R-phase relay 540a, a 540th S-phase relay 540b, a 540th T-phase relay 540c, a 550th R-phase relay 550a, a 550th S-phase relay 550b, and a 550th T-phase relay 550c).

The configuration of the 50th resistance unit 500 is similar to the configuration of the 10th resistance unit 100.

(Effects of Two Regions, which Include Relays, Sandwiching Region Including Resistor Groups)

The state of connection between two resistor groups (such as the 11th R-phase resistor group 11a and the 12th R-phase resistor group 12a) is switched between series and parallel, so that it is easy to cope with a load test of a high-voltage test target power source and a load test of a low-voltage test target power source. On the other hand, in order to switch the state of connection between the two resistor groups, it is necessary to prepare a switch group including a plurality of relays and relay units.

A region (fourth accommodating region 2d) accommodating the relays of the main relay units (such as the third main relay unit 7) and some relays (such as the 13th relay unit 13) of the switch group, and a region (fifth accommodating region 2e) accommodating the remaining relays (such as the 14th relay unit 14) of the switch group sandwich regions accommodating the resistor groups (the first accommodating region 2a to the third accommodating region 2c).

That is, the relays of the switch group are disposed on both sides of the regions accommodating the resistor groups (the first accommodating region 2a to the third accommodating region 2c) in the direction (x direction) in which the regions accommodating said resistor groups are arranged.

Therefore, as compared with an embodiment in which the relays of the switch group and the like are disposed on one side of the regions accommodating the resistor groups (the first accommodating region 2a to the third accommodating region 2c), it is possible to easily wire cables that connect the resistors R of the resistor groups and the relays, and wire the relays. In addition, maintenance at a time of a malfunction or the like is facilitated.

(Effect of Disposing Resistors R Such that Resistors R Extend in x Direction (Providing Rod-Shaped Resistors R Parallel to x Direction))

As compared with an embodiment in which the resistors R are disposed such that the resistors R extend in the y direction, the cable length between an end of the resistor R and a relay of the fourth accommodating region 2d or the fifth accommodating region 2e can be shortened, and the wiring can be easily performed.

(Effect of Connecting Odd Number of Resistors R in Series)

As compared with a case where an even number of resistors R are connected in series, the terminals of the resistors R on the side close to the fourth accommodating region 2d can be easily wired to the relays of the fourth accommodating region 2d, and the terminals of the resistors R on the side close to the fifth accommodating region 2e can be easily wired to the relays of the fifth accommodating region 2e.

(Effect of Relay Switching Performed in Off State of Power Supply)

Since switching of the 14th relay unit 14 and the like is performed in a state where the power supply is cut off using the electromagnetic contactors, such as the 13th relay unit 13, it is possible to prevent accidental power supply to resistor groups and the like to which power should not be supplied.

(Effect of Sharing Short-Circuit Relay)

A short-circuit relay (third main relay unit 7) for neutral-point connection in the star connection is shared, so that the number of relays can be reduced as compared with an embodiment in which a short-circuit relay for neutral-point connection in the first resistance unit 10, and a short-circuit relay for neutral-point connection of the second resistance unit 20 are separately provided.

(Effect of Providing Detection System)

The transmission unit, such as the first R-phase transmission unit a1r, and the receipt unit, such as the first R-phase receipt unit b1r, are disposed and have a positional relationship that the transmission unit and the receipt unit sandwich an inspection target object, such as the 11th R-phase resistor group 11a. On the basis of the radio-wave strength or the like of a signal transmitted from the transmission unit and received by the receipt unit, it is possible to easily detect a failure (such as wire breaking of a resistor R) of said inspection target region.

(Effect of Surrounding Inspection Target Object with Metallic Member)

Since a region, such as the 11th accommodating region 2a1 and the first R-phase air outlet lid 2a23, that surrounds an inspection target region, a transmission unit, and a receipt unit is covered with a metallic member, it is possible to reduce the possibility that radio waves transmitted from the transmission unit reach the receipt unit through a region except the inspection target region.

(Effect of Applying Detection System to Load-Testing Apparatus 1)

Without a change in the internal structure of the load-testing apparatus 1 (in particular, the holding frames), and without an effect on the electric wiring of the resistors R, it is possible to detect a failure inside said holding frames.

In addition, detection of a failure can be performed at a stage before a load test is actually performed.

Since the holding frames, such as the 11th holding frame 2a31, are made of an insulator, radio waves can easily pass through the inside of the holding frames.

(Effect of Providing Grounding Relay Between Short-Circuit Relay, Such as 14th Relay Unit 14, and Grounded Surface)

The grounding relay is connected to the short-circuit side of the short-circuit relay, such as the 14th relay unit 14, so that the resistors R can be grounded easily as compared with an embodiment in which grounding is performed at another place.

(Effect of Grounding Resistor Group)

The resistor group is grounded, so that the length of a region of the resistor R or the cable electrically connected to the grounded surface varies for a state where there is no wire breaking and a state where there is wire breaking. Therefore, a difference is likely to occur in the effect on radio waves from the transmission unit, and a difference is likely to appear in the radio-wave strength of a signal obtained by the receipt unit.

(Application Example of Metallic Member)

In the first embodiment and the like, an example in which a region surrounding the inspection target object, the transmission unit, and the receipt unit includes a metallic member has been described.

However, said region may consist of a radio-wave-shielding member different from the metallic member. Alternatively, a radio-wave-shielding member may be attached to, included in, or coated on the surface or the like of said region.

(Example of Application to Inspection Target Object Except Load-Testing Apparatus 1)

In the first embodiment and the like, on the assumption that the resistors R and the like of the load-testing apparatus 1 are an inspection target object, an example has been described in which the transmission unit and the receipt unit are provided around the resistor groups (around the holding frames).

However, a region including an object (inspection target object) other than the load-testing apparatus 1 may be surrounded with a radio-wave-shielding member, and in the region surrounded with said radio-wave-shielding member, a transmission unit and a receipt unit may be disposed and have a positional relationship that the transmission unit and the receipt unit sandwich said inspection target object.

For example, conceivable is an embodiment in which a user who has entered a toilet is an inspection target object, a region including said toilet is surrounded with a radio-wave-shielding member, and in the region surrounded with said radio-wave-shielding member, a transmission unit and a receipt unit are disposed and have a positional relationship that the transmission unit and the receipt unit sandwich said user

In this case, a signal transmitted from the transmission unit reaches the receipt unit through the body of the user. On the basis of the degree of variation in the radio-wave strength of the signal received by the receipt unit according to the health condition of the user, the health condition of said user can be specified.

Although some embodiments of the present invention have been described, these embodiments have been presented as examples, and it is not intended to limit the scope of the invention. These embodiments can be implemented in other various embodiments, and various omission, substitution, and change can be made without departing from the gist of the invention. These embodiments and modifications thereof are included in the scope and gist of the invention and are included in the invention described in the claims and the equivalent scope thereof.

### REFERENCE SIGNS LIST

1 Load-testing apparatus
2 Housing
2a First accommodating region (R-phase-resistor-group-accommodating region)
2a1 11th accommodating region (first R-phase-resistor-group-accommodating region)
2a2 12th accommodating region (second R-phase-resistor-group-accommodating region)
2a11 First R-phase air inlet
2a12 Second R-phase air inlet
2a13 First R-phase air inlet lid
2a14 Second R-phase air inlet lid
2a21 First R-phase air outlet
2a22 Second R-phase air outlet
2a23 First R-phase air outlet lid
2a24 Second R-phase air outlet lid
2a31 11th holding frame
2a32 12th holding frame
2b Second accommodating region (S-phase-resistor-group-accommodating region)
2b1 21st accommodating region (first S-phase-resistor-group-accommodating region)
2b2 22nd accommodating region (second S-phase-resistor-group-accommodating region)
2b11 First S-phase air inlet
2b12 Second S-phase air inlet
2b13 First S-phase air inlet lid
2b14 Second S-phase air inlet lid
2b21 First S-phase air outlet
2b22 Second S-phase air outlet
2b23 First S-phase air outlet lid
2b24 Second S-phase air outlet lid
2b31 21st holding frame
2b32 22nd holding frame
2c Third accommodating region (T-phase-resistor-group-accommodating region)
2c1 31st accommodating region (first T-phase-resistor-group-accommodating region)
2c2 32nd accommodating region (second T-phase-resistor-group-accommodating region)
2c11 First T-phase air inlet
2c12 Second T-phase air inlet
2c13 First T-phase air inlet lid
2c14 Second T-phase air inlet lid
2c21 First T-phase air outlet
2c22 Second T-phase air outlet
2c23 First T-phase air outlet lid
2c24 Second T-phase air outlet lid
2c31 31st holding frame
2c32 32nd holding frame
2d Fourth accommodating region (first relay-unit-accommodating region)
2e Fifth accommodating region (second relay-unit-accommodating region)
5 First main relay unit
6 Second main relay unit (for low-voltage connection)
7 Third main relay unit (for high-voltage connection, and for neutral-point connection)
8 First fine-adjustment relay unit
9 Second fine-adjustment relay unit
10 First resistance unit
11a 11th R-phase resistor group
11b 11th S-phase resistor group
11c 11th T-phase resistor group
12a 12th R-phase resistor group
12b 12th S-phase resistor group
12c 12th T-phase resistor group
13 13th relay unit
14 14th relay unit (for low-voltage neutral-point connection of first resistance unit)
14g 14th grounding relay
15 15th relay unit
20 Second resistance unit
21a 21st R-phase resistor group
21b 21st S-phase resistor group
21c 21st T-phase resistor group
22a 22nd R-phase resistor group
22b 22nd S-phase resistor group
22c 22nd T-phase resistor group
23 23rd relay unit
24 24th relay unit (for low-voltage neutral-point connection of second resistance unit)
24g 24th grounding relay
25 25th relay unit
30 Third resistance unit
31a 31st R-phase resistor group
31b 31st S-phase resistor group
31c 31st T-phase resistor group
32a 32nd R-phase resistor group
32b 32nd S-phase resistor group
32c 32nd T-phase resistor group
33 33rd relay unit
34 34th relay unit (for low-voltage neutral-point connection of third resistance unit)
34g 34th grounding relay
35 35th relay unit
40 Fourth resistance unit
41a 41st R-phase resistor group
41b 41st S-phase resistor group
41c 41st T-phase resistor group
42a 42nd R-phase resistor group
42b 42nd S-phase resistor group
42c 42nd T-phase resistor group
43 43rd relay unit
44 44th relay unit (for low-voltage neutral-point connection of fourth resistance unit)
44g 44th grounding relay
45 45th relay unit
50 Fifth resistance unit
51a 51st R-phase resistor group
51b 51st S-phase resistor group
51c 51st T-phase resistor group
52a 52nd R-phase resistor group
52b 52nd S-phase resistor group
52c 52nd T-phase resistor group
53 53rd relay unit
54 54th relay unit (for low-voltage neutral-point connection of fifth resistance unit)
54g 54th grounding relay
55 55th relay unit
60 Sixth resistance unit
61a 61st R-phase resistor group
61b 61st S-phase resistor group
61c 61st T-phase resistor group
62a 62nd R-phase resistor group
62b 62nd S-phase resistor group
62c 62nd T-phase resistor group
63 63rd relay unit
64 64th relay unit (for low-voltage neutral-point connection of sixth resistance unit)
64g 64th grounding relay
65 65th relay unit
70 Seventh resistance unit
71a 71st R-phase resistor group
71b 71st S-phase resistor group
71c 71st T-phase resistor group
72a 72nd R-phase resistor group
72b 72nd S-phase resistor group
72c 72nd T-phase resistor group
73 73rd relay unit
74 74th relay unit (for low-voltage neutral-point connection of seventh resistance unit)
74g 74th grounding relay
75 75th relay unit
80 Cooling unit
81a First R-phase-cooling unit
82a Second R-phase-cooling unit
81b First S-phase-cooling unit
82b Second S-phase-cooling unit
81c First T-phase-cooling unit
82c Second T-phase-cooling unit
91 Operation unit
93 Terminal unit
100 10th resistance unit
110a 110th R-phase resistor group
110b 110th S-phase resistor group
110c 110th T-phase resistor group
120a 120th R-phase resistor group
120b 120th S-phase resistor group
120c 120th T-phase resistor group
140a 140th R-phase relay (for low-voltage neutral-point connection of 10th resistance unit)
140b 140th S-phase relay (for low-voltage neutral-point connection of 10th resistance unit)
140c 140th T-phase relay (for low-voltage neutral-point connection of 10th resistance unit)
140g 140th grounding relay
150a 150th R-phase relay
150b 150th S-phase relay
150c 150th T-phase relay
200 20th resistance unit
210a 210th R-phase resistor group
210b 210th S-phase resistor group
210c 210th T-phase resistor group
220a 220th R-phase resistor group
220b 220th S-phase resistor group
220c 220th T-phase resistor group
240a 240th R-phase relay (for low-voltage neutral-point connection of 20th resistance unit)
240b 240th S-phase relay (for low-voltage neutral-point connection of 20th resistance unit)
240c 240th T-phase relay (for low-voltage neutral-point connection of 20th resistance unit)
240g 240th grounding relay
250a 250th R-phase relay
250b 250th S-phase relay
250c 250th T-phase relay
300 30th resistance unit
310a 310th R-phase resistor group
310b 310th S-phase resistor group
310c 310th T-phase resistor group
320a 320th R-phase resistor group
320b 320th S-phase resistor group
320c 320th T-phase resistor group
340a 340th R-phase relay (for low-voltage neutral-point connection of 30th resistance unit)
340b 340th S-phase relay (for low-voltage neutral-point connection of 30th resistance unit)
340c 340th T-phase relay (for low-voltage neutral-point connection of 30th resistance unit)
340g 340th grounding relay
350a 350th R-phase relay
350b 350th S-phase relay
350c 350th T-phase relay
400 40th resistance unit
410a 410th R-phase resistor group
410b 410th S-phase resistor group
410c 410th T-phase resistor group
420a 420th R-phase resistor group
420b 420th S-phase resistor group
420c 420th T-phase resistor group
440a 440th R-phase relay (for low-voltage neutral-point connection of 40th resistance unit)
440b 440th S-phase relay (for low-voltage neutral-point connection of 40th resistance unit)
440c 440th T-phase relay (for low-voltage neutral-point connection of 40th resistance unit)
440g 440th grounding relay
450a 450th R-phase relay
450b 450th S-phase relay
450c 450th T-phase relay
500 50th resistance unit
510a 510th R-phase resistor group
510b 510th S-phase resistor group
510c 510th T-phase resistor group
520a 520th R-phase resistor group
520b 520th S-phase resistor group
520c 520th T-phase resistor group
540a 540th R-phase relay (for low-voltage neutral-point connection of 50th resistance unit)
540b 540th S-phase relay (for low-voltage neutral-point connection of 50th resistance unit)
540c 540th T-phase relay (for low-voltage neutral-point connection of 50th resistance unit)
540g 540th grounding relay
550a 550th R-phase relay
550b 550th S-phase relay
550c 550th T-phase relay
ar R-phase transmission unit
a1r First R-phase transmission unit
a2r Second R-phase transmission unit
a1s First S-phase transmission unit
a2s Second S-phase transmission unit
a1t First T-phase transmission unit
a2t Second T-phase transmission unit
br R-phase receipt unit
b1r First R-phase receipt unit
b2r Second R-phase receipt unit
b1s First S-phase receipt unit
b2s Second S-phase receipt unit
b1t First T-phase receipt unit
b2t Second T-phase receipt unit
f1 First frequency band (not passing through radio-wave-shielding member)
f2 Second frequency band (passing through radio-wave-shielding member)
t1 First time period (time period during which signal is transmitted)
t2 Second time period (time lag until next signal is transmitted)

1. An inspection system comprising:
a transmission unit that transmits a signal to inspect an inspection target object;
a receipt unit that receives the signal from the transmission unit; and
a totaling unit, wherein
the transmission unit and the receipt unit have a positional relationship that the transmission unit and the receipt unit sandwich the inspection target object, and
on a basis of at least one of radio-wave strength or signal waveform of the signal from the transmission unit and received by the receipt unit, the totaling unit determines whether or not there is a failure in the inspection target object.

2. The inspection system according to claim 1, wherein
the inspection target object is resistors of a load-testing apparatus,
a holding frame that holds the resistors is made of an insulator,
the holding frame, the transmission unit, and the receipt unit are surrounded by a radio-wave-shielding member, and
the load-testing apparatus is provided with a grounding relay to which the resistors are grounded when the inspection is performed.

3. The inspection system according to claim 2, wherein in the load-testing apparatus, a lid is provided for at least one of an air outlet and an air inlet, the lid includes a radio-wave-shielding member, and the lid is turned into an open state when a load test using the resistors is performed, and is turned into a closed state when the inspection is performed.

4. The inspection system according to claim 2, wherein
the load-testing apparatus is for performing a load test of a three-phase alternating-current generator, and
the load-testing apparatus is provided with a relay for short-circuiting R-phase, S-phase, and T-phase resistors of the resistors, and the grounding relay, which is provided between the relay and a grounded surface and is for performing on/off-switching of grounding of the resistors.

5. The inspection system according to claim 1, wherein
at least the inspection target object, the transmission unit, and the receipt unit are surrounded by a radio-wave-shielding member, and
in a communication between the transmission unit and the receipt unit, identification information is transmitted to an outside while wireless communication is in an on state, and the communication is performed with wireless communication of a frequency that does not pass through the radio-wave-shielding member.

6. The inspection system according to claim 5, wherein communication between the receipt unit and the totaling unit is performed with wired communication or wireless communication of a frequency that passes through the radio-wave-shielding member.
